(19) United States
(12) Patent Application Publication
(10) Pub. No.: US 2021/0125878 A1
(43) Pub. Date: Apr. 29, 2021

(54) SPLIT WELL IMPLANTATION FOR CMOS AND PERIPHERAL DEVICES

(71) Applicant: SEMICONDUCTOR COMPONENTS INDUSTRIES, LLC, Phoenix, AZ (US)

(72) Inventors: Thierry Coffi Herve YAO, Portland, OR (US); Moshe AGAM, Portland, OR (US)

(73) Assignee: SEMICONDUCTOR COMPONENTS INDUSTRIES, LLC, Phoenix, AZ (US)

(21) Appl. No.: 16/832,624

(22) Filed: Mar. 27, 2020

Related U.S. Application Data
(60) Provisional application No. 62/925,250, filed on Oct. 24, 2019.

(51) Int. Cl. H01L 21/8238; H01L 21/266

(52) U.S. Cl. CPC H01L 21/823892; H01L 21/266

(57) ABSTRACT

Manufacturing processes leverage process steps used during CMOS formation to form one or more additional type(s) of devices on the same substrate used for the CMOS formation, and at least partially in parallel with the CMOS formation processes. A first layer of implant wells may be formed at a first depth in a substrate using a first mask, and then a second layer of implant wells may be formed at a second, more shallow depth, using a second mask. CMOS devices that are part of a CMOS platform may be formed using some of the wells, while peripheral devices may be formed using remaining wells.

### CROSS-REFERENCE TO RELATED APPLICATIONS

This application claims the benefit of U.S. Provisional Application No. 62/925,250, filed on Oct. 24, 2019, which is hereby incorporated by reference in its entirety. This application is also related to the U.S. application with Attorney Docket No. ONS03635US, filed on the same date herewith, which is hereby incorporated by reference in its entirety.

### TECHNICAL FIELD

This description relates to semiconductor fabrication techniques.

### BACKGROUND

Complementary metal-oxide-semiconductor (CMOS) devices are widely-used in the construction of integrated circuit (IC) microchips. In many cases, it is desirable to include other types of transistor-based devices on CMOS-based microchips. For example, such approaches may enable mixed voltage performance, device miniaturization, and other advantages, as well as optimizations of the overall microchip for specific applications (e.g., low noise applications). However, associated fabrication processes are often inefficient and expensive.

### SUMMARY

According to one general aspect, a method of making semiconductor devices includes performing a first implantation into a substrate at a first depth using a first mask, the first mask having at least a first opening defining a first well and a second opening defining a second well, performing a second implantation into the substrate at a second depth using a second mask, the second mask having at least a third opening defining a third well and a fourth opening defining a fourth well, and the second depth being closer to an implant surface of the substrate than the first depth, forming a CMOS device using at least the first well and the third well, and forming a peripheral device using at least the second well and the fourth well.

According to another general aspect, a method of making semiconductor devices includes forming CMOS devices of a CMOS platform on a substrate, the CMOS devices being formed using at least a first deep well implanted using a first mask and at least a first shallow well implanted using a second mask, and forming at least one peripheral device on the substrate, using at least a second deep well implanted using the first mask, and at least a second shallow well implanted using the second mask.

According to another general aspect, a method of making semiconductor devices includes forming CMOS devices of a CMOS platform on a substrate, the CMOS devices being formed using at least a first deep well implanted using a first mask and at least a first shallow well implanted using a second mask, and forming at least one double-diffused metal oxide transistor (DMOS) in the substrate, the DMOS transistor being formed using at least a second deep well implanted using the first mask, and at least a second shallow well implanted using the second mask.

The details of one or more implementations are set forth in the accompanying drawings and the description below. Other features will be apparent from the description and drawings, and from the claims.

### BRIEF DESCRIPTION OF THE DRAWINGS

FIG. 1 is a diagram illustrating a split well implantation process for CMOS and peripheral devices.

FIG. 2 is a flowchart illustrating example operations of the example of FIG. 1.

FIG. 3 illustrates an example of a cross-section of a CMOS device that may be formed using the techniques of FIGS. 1 and 2.

FIG. 4 illustrates a cross-section of an example isolation scheme for CMOS devices that may be implemented using the techniques of FIGS. 1 and 2.

FIG. 5 illustrates a first example of a peripheral device formed using the techniques of FIGS. 1 and 2, a vertical DMOS.

FIG. 6 illustrates an example top view of the vertical DMOS of FIG. 5.

FIG. 7 illustrates a cross section view of a first operation for forming the vertical DMOS of FIGS. 5 and 6.

FIG. 8 illustrates a cross section view of a second operation for forming the vertical DMOS of FIGS. 5 and 6.

FIG. 9 illustrates a cross section view of a third operation for forming the vertical DMOS of FIGS. 5 and 6.

FIG. 10 illustrates a cross section view of a fourth operation for forming the vertical DMOS of FIGS. 5 and 6.

FIG. 11 illustrates a cross section view of a fifth operation for forming the vertical DMOS of FIGS. 5 and 6.

FIG. 12 illustrates a cross section view of a sixth operation for forming the vertical DMOS of FIGS. 5 and 6.

FIG. 13 illustrates a cross section view of a seventh operation for forming the vertical DMOS of FIGS. 5 and 6.

FIG. 14 is a flowchart illustrating the example operations of FIGS. 7-13 in constructing the vertical DMOS of FIGS. 5 and 6.

FIG. 15 is a cross section of an example simulation of the vertical DMOS of FIGS. 5 and 6.

FIG. 16 is an example circuit using the vertical DMOS of FIGS. 5 and 6 with a CMOS transistor.

FIG. 17 illustrates a cross section view of a first operation for forming a lateral DMOS.

FIG. 18 illustrates a cross section view of a second operation for forming a lateral DMOS.

FIG. 19 illustrates a cross section view of a third operation for forming a lateral DMOS.

FIG. 20 illustrates a cross section view of a fourth operation for forming a lateral DMOS.

FIG. 21 illustrates a cross section view of a fifth operation for forming a lateral DMOS.

FIG. 22 is a flowchart illustrating the example operations of FIGS. 17-21 for forming a lateral DMOS.

FIG. 23 illustrates a cross section view of a simulation of the lateral DMOS of FIGS. 17-22.

FIG. 24 illustrates a cross section view of a first operation for forming a low voltage (LV) floating body NMOS.

FIG. 25 illustrates a cross section view of a second operation for forming a LV floating body NMOS.

FIG. 26 illustrates a cross section view of a third operation for forming a LV floating body NMOS.

FIG. 27 illustrates a cross section view of a fourth operation for forming a LV floating body NMOS.

FIG. 28 illustrates a cross section view of a fifth operation for forming a LV floating body NMOS.

FIG. 29 is a flowchart illustrating example operations for forming the LV floating body NMOS of FIGS. 24-28.

FIG. 30 is a first example circuit built using the LV floating body NMOS of FIGS. 24-29.

FIG. 31 is a second example circuit built using the LV floating body NMOS of FIGS. 24-29.

FIG. 32 is a cross section of a simulation of the LV floating body NMOS of FIGS. 24-29, and an associated current-voltage graph.

FIG. 33 is a cross section of a first operation for forming a Junction Field Effect Transistor (JFET).

FIG. 34 is a cross section of a second operation for forming a JFET.

FIG. 35 is a cross section of a third operation for forming a JFET.

FIG. 36 is a cross section of a fourth operation for forming a JFET.

FIG. 37 is a flowchart illustrating example operations for forming the JFET of FIGS. 33-36.

FIG. 38 is a first cross section of a simulation of the JFET of FIGS. 33-37.

FIG. 39 is a second cross section of a simulation of the JFET of FIGS. 33-37.

FIG. 40 is a third cross section of a simulation of the JFET of FIGS. 33-37.

FIG. 41 is a fourth cross section of a simulation of the JFET of FIGS. 33-37.

FIG. 42 illustrates a cross section of a second example implementation of a JFET.

FIG. 43 illustrates a cross section of a third example implementation of a JFET.

FIG. 44 illustrates a cross section of a first example operation for forming a (Bipolar Junction Transistor) BJT.

FIG. 45 illustrates a cross section of a second example operation for forming a BJT.

FIG. 46 illustrates a cross section of a third example operation for forming a BJT.

FIG. 47 illustrates a cross section of a fourth example operation for forming a BJT.

FIG. 48 is a flowchart illustrating example operations for forming the BJT of FIGS. 44-47.

FIG. 49 is a first cross section of a simulation of the BJT of FIGS. 44-48.

FIG. 50 is a second cross section of a simulation of the BJT of FIGS. 44-48.

FIG. 51 is a third cross section of a simulation of the BJT of FIGS. 44-48.

FIG. 52 is a first example current-voltage graph for the BJT of FIGS. 44-48.

FIG. 53 is a second example current-voltage graph for the BJT of FIGS. 44-48.

FIG. 54 illustrates a cross section of a second example implementation of a BJT.

FIG. 55 illustrates a cross section of a third example implementation of a BJT.

### DETAILED DESCRIPTION

As described in detail below, manufacturing processes may be implemented that leverage process steps used during CMOS formation to form one or more additional type(s) of devices on the same substrate used for the CMOS formation, and at least partially in parallel with the CMOS formation processes. For example, a first layer of implant wells (e.g., first Nwells) may be formed at a first depth in a substrate using a first mask, and then a second layer of implant wells may be formed at a second, more shallow depth, using a second mask.

In this way, it is possible to form desired combinations of implant wells at different depths. For example, a shallow implant well may be stacked adjacent to a deep implant well, or shallow and deep implant wells may be partially or completely offset from one another within a substrate.

CMOS devices that are part of a CMOS platform may be formed using some of the wells, while peripheral devices may be formed using remaining wells. Therefore, use of separate or additional process modules to form all or parts of the peripheral devices may be minimized or avoided.

In some implementations, the first mask and the second mask may have different levels of implant precision, so that, for example, it is possible to form relatively small or narrow shallow wells when required for formation of the peripheral devices, and/or to form CMOS and peripheral devices closer to one another, while still maintaining desired levels of device isolation. Accordingly, improvements in device performance and device density may be obtained, and process efficiency may be increased.

In various implementations, more than two (i.e., three or more) different implant well masks may be used to form implant wells shared by CMOS and peripheral device processing. Moreover, CMOS process steps, used to form primary CMOS devices of the CMOS platform, may be leveraged (e.g., shared with peripheral devices) prior to, in between, or after the use of any such number of implant well masks.

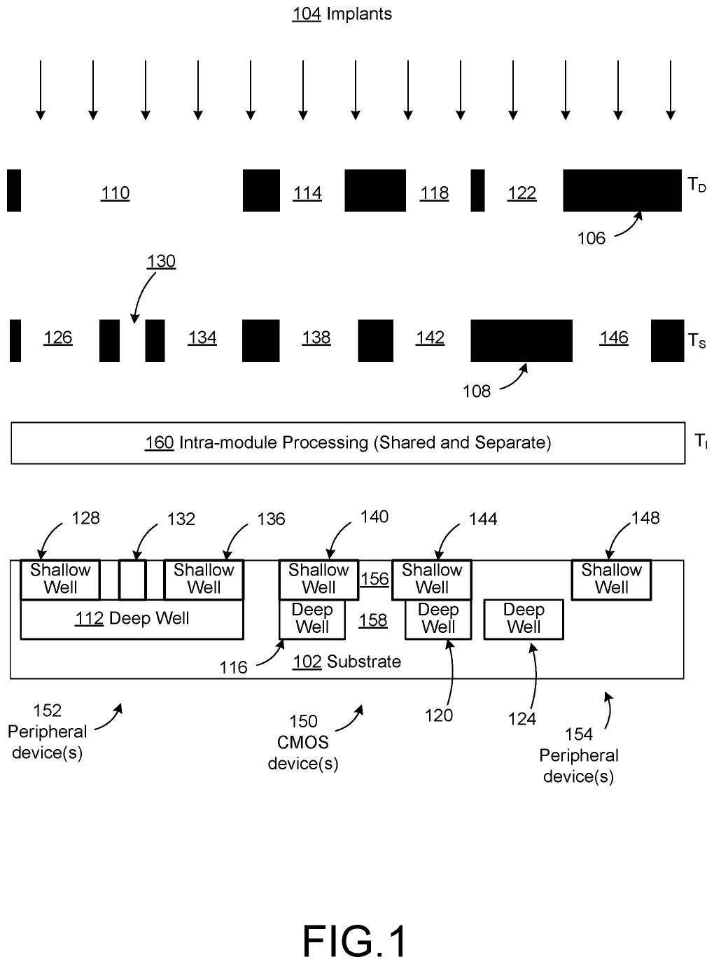

FIG. 1 is a diagram illustrating a split well implantation process for CMOS and peripheral devices. In the example of FIG. 1, a substrate 102 is subjected to multiple rounds of dopant implantation, represented by implants 104. A first mask 106 is used at a first time to form implanted wells at a first depth, and a second mask 108 is used at a second time to form implanted wells at a second depth that is closer to a surface of the substrate 102. In example implementations, the first mask 106 may be used to form relatively deep wells, and may be referred to as a deep mask, while the second mask 108 may be used to form relatively shallow wells, and may be referred to as a shallow mask.

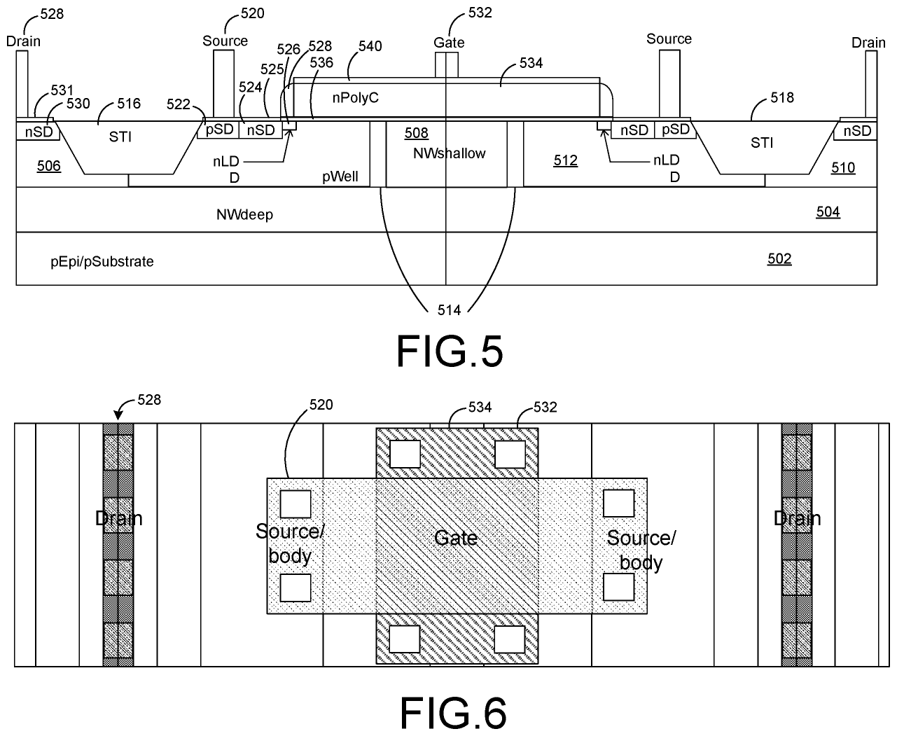

In more detail, the first mask 106 includes an opening 110 used to define a deep well 112, an opening 114 used to define a deep well 116, an opening 118 used to define a deep well 120, and an opening 122 used to define a deep well 124. Similarly, the second mask 108 includes an opening 126 used to define a shallow well 128, an opening 130 used to define a shallow well 132, an opening 134 used to define a shallow well 136, an opening 138 used to define a shallow well 140, an opening 142 used to define a shallow well 144, and an opening 146 used to define a shallow well 148. In some implementations, such as in the examples of FIGS. 5-16, below, the shallow wells 128, 136 may illustrate a cross-section of a diffusion ring.

In example implementations, the substrate 102 may be primarily devoted to construction of a CMOS platform that includes many NPN/PNP transistors and related devices and structures, including, e.g., isolation structures and metal contacts. In conventional processes, it is possible to complete constructions of such a CMOS platform and then subsequently construct additional, peripheral devices using reserved areas of the substrate 102, in two or more separate process modules. For example, the CMOS platform may be constructed in a first process module(s) that uses a first mask to implant all CMOS-related wells, while peripheral devices may subsequently be constructed in a second process module(s), using at least a second mask.

In the example of FIG. 1, however, it is possible to form all desired wells for both CMOS and peripheral devices within a single process module, using the masks 106, 108 to split the well formation process into separate masking steps. As illustrated and described with respect to FIG. 1, desired wells may be formed with a high degree of flexibility and efficiency, so that many different types of peripheral devices may be formed, examples of which are described and illustrated herein.

Moreover, it is possible to form such circuits in an efficient, cost-effective manner. For example, an existing CMOS platform process flow may be enhanced to form any of the peripheral devices described herein, and many others, by simply altering the characteristics (e.g., openings, thicknesses) of the masks 106, 108.

Other advantages may be obtained, as well. For example, implants of the implants 104 used to form the various deep wells 112, 116, 120, 124 may be higher in energy than implants used to form the various shallow wells 128, 132, 136, 140, 144, 148. Consequently, the second, shallow mask 108, due to being used for relatively lower-energy implantations, may be thinner and therefore more precise than the first, deep mask 106, so that shallow wells (e.g., the shallow well 132) may be formed with greater precision.

In other examples, it may occur that portions of the substrate 102 may be used to provide isolation between two or more of the various wells. For example, an area 156 of the substrate 102 may provide isolation between shallow wells 140, 144, while an area 158 may provide isolation between deep wells 116, 120. As illustrated, the area 156 is smaller than the area 158, thereby permitting the shallow wells 140, 144 to be formed closer to one another than the deep wells 116, 120.

Such a scenario may be advantageous, for example, when less isolation is required at different depths of the substrate 102 (e.g., due to depth-dependent magnitudes of electrical fields). In such cases, the multi-mask approach of FIG. 1 enables optimization and miniaturization of isolation widths, and thereby enables smaller device sizes, and greater device densities, on the substrate 102.

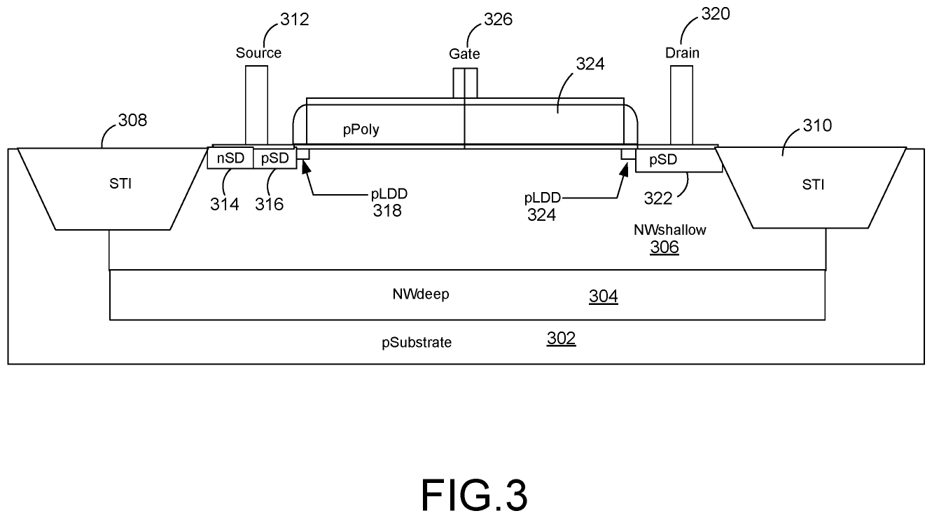

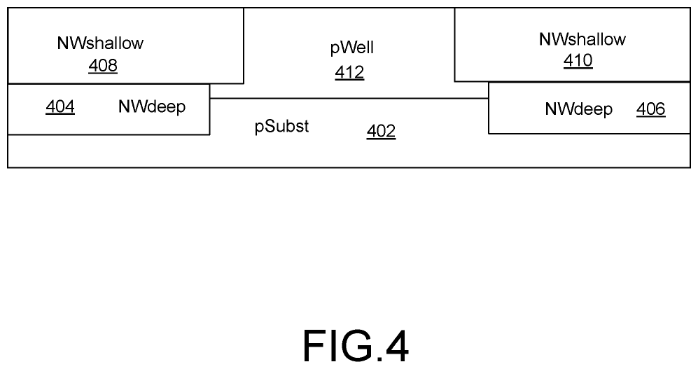

In addition to the use of masks 106, 108 to form desired combinations of deep and shallow wells, intra-module, shared and separate processing 160 may occur to define individual CMOS devices and peripheral devices, and combinations thereof. For example, in the simplified example of FIG. 1, an area 150 that includes shallow wells 140, 144 and deep wells 116, 120 may be used to form a CMOS device, such as a PNP or NPN transistor of a CMOS platform (as illustrated in more detailed examples with respect to FIGS. 3 and 4).

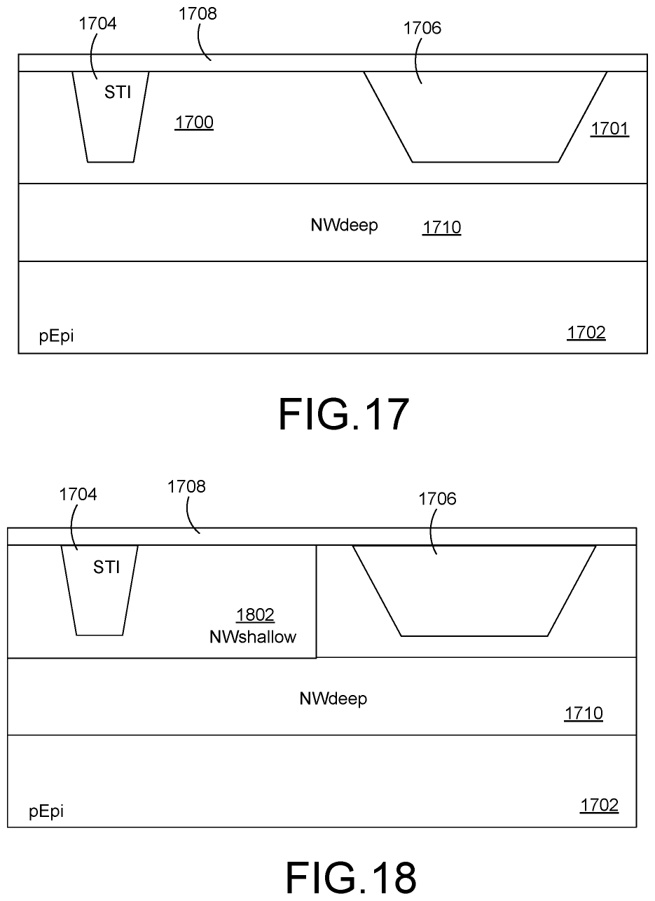

Meanwhile, an area 152 that includes deep well 112 and shallow wells 128, 132, 136 may be used to form a peripheral device, such as a vertical DMOS (double-diffused MOS) transistor, which may be used, e.g., for nonvolatile memory circuits (as illustrated in more detailed examples with respect to FIGS. 5-16). The deep well 124 and the shallow well 148 in an area 154 may be used for one or more additional peripheral devices, as well. Moreover, many other variations and combinations of shallow and deep wells may be used, examples of which are illustrated and described below with respect to FIGS. 17-55.

As referenced above and described below in detail, intra-module processing 160 refers to, and includes, any potential processing steps that may occur within the process module in which the deep mask 106 and the shallow mask 108 are used. Such intra-module processing may be referred to as shared when referencing process steps that are implemented together for both CMOS and peripheral devices formed in the substrate 102.

For example, both the CMOS device(s) in the area 150 and one or more peripheral devices in the area 152 may require implantation of additional well(s) of an opposite doping type (e.g., p-type) than a doping type (e.g., n-type) of the various shallow wells 128, 132, 136, 140, 144. In such scenarios, the intra-module processing 160 may represent an additional mask (not shown separately in FIG. 1) used to implant p-type dopants in desired regions of both areas 150, 152.

Such shared processing may include any processing steps that may be required by groups of CMOS and peripheral devices (including different types of peripheral devices). For example, such processing steps may include silicide or other depositions, etching or other removal processes, annealing processes, or contact(s) formation. Shared processing may also refer to processing steps that facilitate formation of CMOS and peripheral devices, such as steps for forming isolation regions or structures.

The various types of peripheral devices that may be included may require many different processing steps, some of which may not overlap directly with formation of corresponding CMOS devices, or other peripheral devices. In such cases, for example, CMOS devices may be masked while separate processing proceeds for the peripheral devices. Nonetheless, such separate processing may occur without requiring movement of the substrate 102 to a separate processing module, due to use of the techniques described herein.

In the present description, by way of notation and terminology, a time at which the deep mask 106 is used may be referred to as T_{D}, while a time at which the shallow mask 108 is used may be referred to as T_{S}. Processing steps of intra-module processing 160 may occur at one or more time periods referred to as T_{I}. Processing steps that occur at times T_{I} may occur before, interspersed with, or after the times T_{D} and T_{S}. For example, isolation structures may be formed in the substrate 102 at an initial T_{I}, followed by use of the deep mask 106 at time T_{D}, followed by use of the shallow mask 108 at time T_{S}, followed by a subsequent T_{I} during which shared processing occurs for CMOS/peripheral devices, and followed by a final T_{I} at which any remaining separate processing occurs for CMOS devices and peripheral devices.

In the present description, the substrate 102 is generally referred to as p-type, so that the various wells are referred to as Nwells. However, it will be appreciated that reverse dopant types may be used, as well. Further, as used herein, the term peripheral refers to devices that are peripheral in number and/or function to the primary circuitry of the CMOS platform, and not necessarily to a physical periphery of the substrate 102.

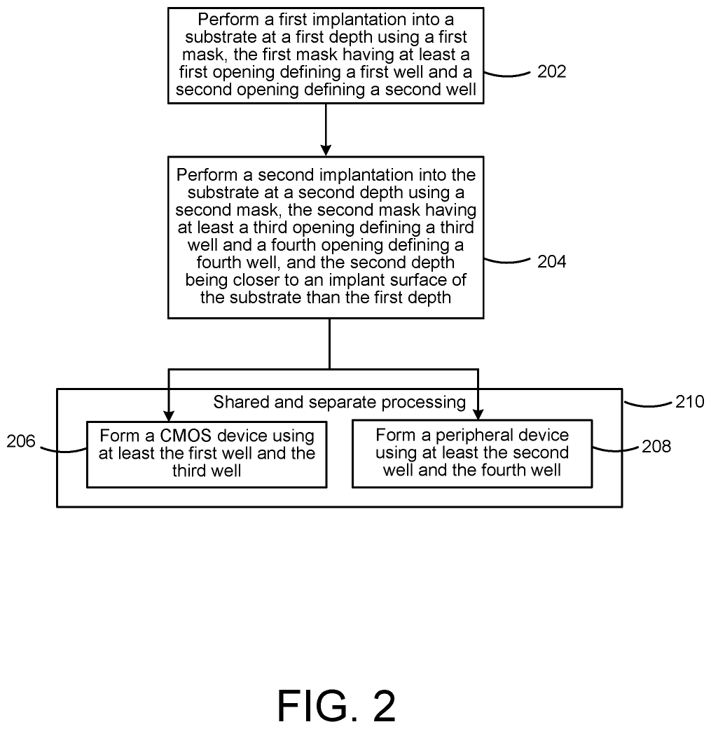

FIG. 2 is a flowchart illustrating example operations of the example of FIG. 1. In the example of FIG. 2, a first implantation into a substrate may be performed at a first depth using a first mask, with the first mask having at least a first opening defining a first well and a second opening defining a second well (202). For example, with reference to FIG. 1, the first mask 106 may be used to implant at least two of the example deep wells 112, 116, 120, 124. In various embodiments, the implants may be performed in any desired manner. For example, multiple diffusions may be performed so as to establish a desired doping gradient within the deep wells 112, 116, 120, 124.

A second implantation into the substrate may be performed at a second depth using a second mask, the second mask having at least a third opening defining a third well and a fourth opening defining a fourth well, with the second depth being closer to an implant surface of the substrate than the first depth (204). For example, with reference to FIG. 1, the second mask 108 may be used to implant at least two of the example shallow wells 128, 132, 136, 140, 144, 148, which, as illustrated and described, may be formed closer to a surface of the substrate 102 at which implantation occurs.

A CMOS device may be formed using at least the first well and the third well (206). For example, a CMOS device may be formed using the deep well 116 and the shallow well 140, or using the deep well 120 and the shallow well 144.

A peripheral device may be formed using at least the second well and the fourth well (208). For example, a peripheral device may be formed using the deep well 112, and one or more of the shallow wells 128, 132, 136.

In FIG. 2, shared and separate processing (210) is illustrated as being inclusive of both CMOS processing 206 and peripheral device processing 208. As described above with respect to FIG. 1, shared processing may include intra-module processing steps in which one or more steps of the CMOS processing 206 and the peripheral device processing 208 occur in parallel. Separate processing may include, for example, intra-module processing steps in which steps of the CMOS processing 206 (including the shared steps) are completed, followed by completion of remaining steps of the peripheral device processing 208, in series therewith. In some implementations, such additional, separate steps for finalizing the peripheral devices may not be necessary. As described, the ability to execute such shared and separate processing within a process module enables greater process efficiencies, and reduced processing costs.

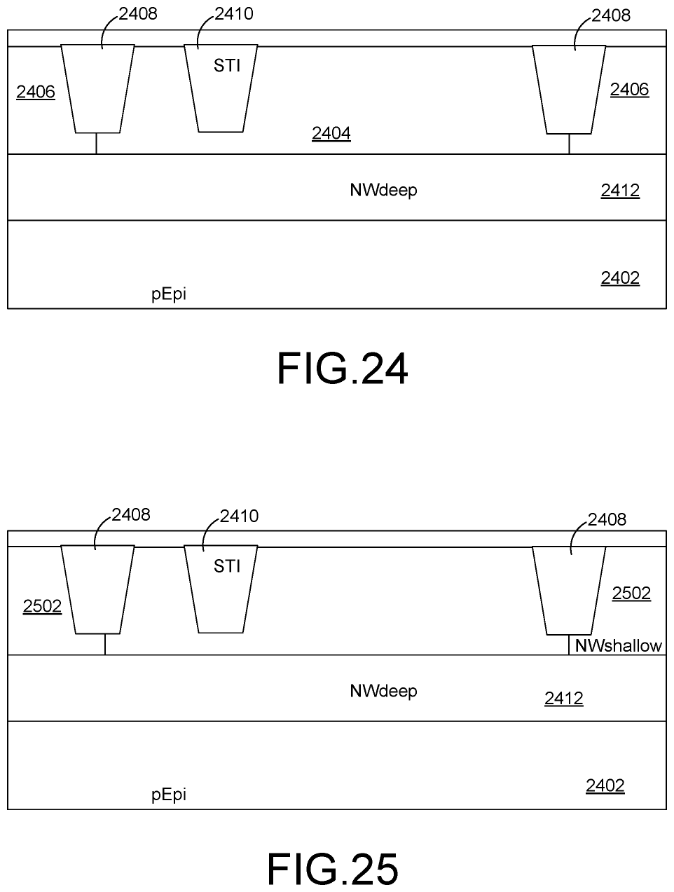

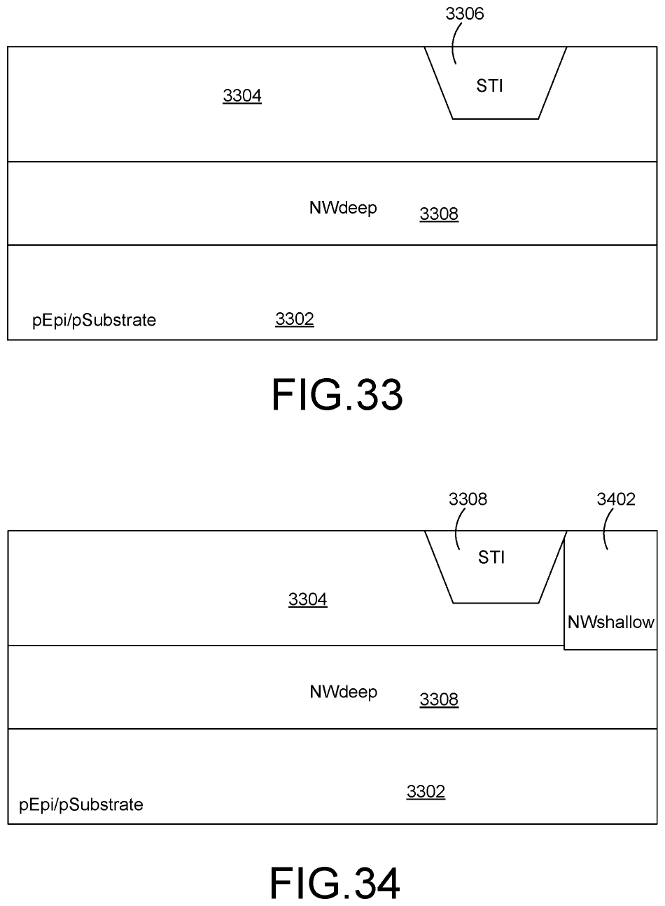

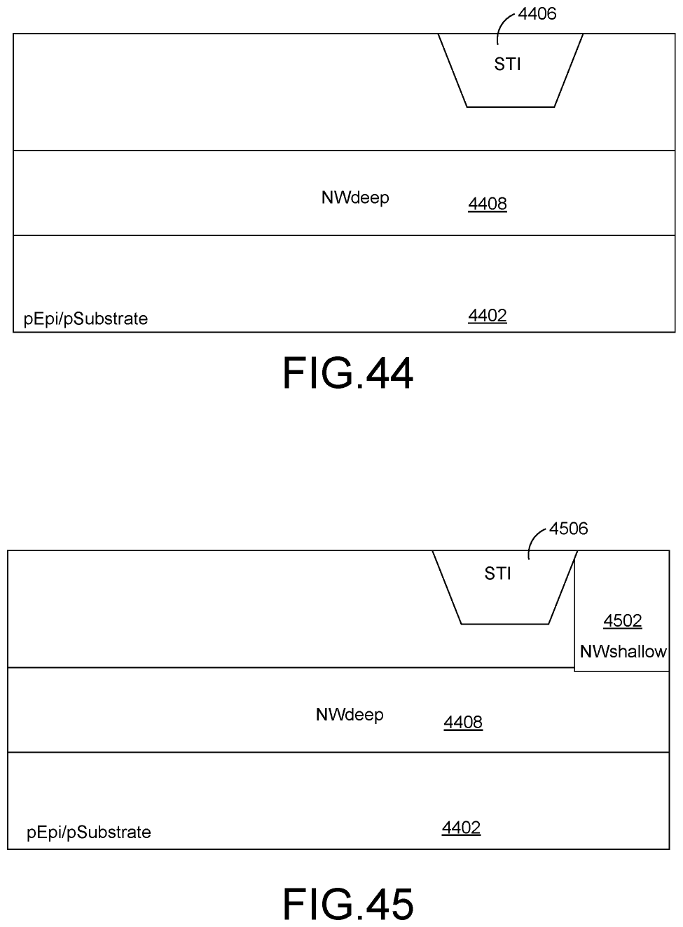

In the following, FIGS. 3 and 4 illustrate example implementations and aspects of CMOS devices formed using the techniques of FIGS. 1 and 2. FIGS. 5-16 illustrate example implementations and aspects of a first example peripheral device using the techniques of FIGS. 1 and 2, a vertical DMOS. FIGS. 17-23 illustrate example implementations and aspects of a second example peripheral device using the techniques of FIGS. 1 and 2, a lateral DMOS. FIGS. 24-32 illustrate example implementations and aspects of a third example peripheral device using the techniques of FIGS. 1 and 2, a floating body low-voltage (LV) NMOS. FIGS. 33-43 illustrate example implementations and aspects of a fourth example peripheral device using the techniques of FIGS. 1 and 2, an isolated junction field effect transistor (JFET). FIGS. 44-55 illustrate example implementations and aspects of a fifth example peripheral device using the techniques of FIGS. 1 and 2, a bipolar junction transistor (BJT).

In the following, it is assumed that functional, operational characteristics of a CMOS devices and the various peripheral devices, by themselves, are known. Moreover, the described devices are provided as examples, and other CMOS and peripheral devices may be used, as well. Consequently, functional and operational characteristics of the various CMOS and peripheral devices are not described here in detail, except as may be necessary or helpful to understand example benefits of using the techniques of FIGS. 1 and 2 to form each peripheral device, or similar peripheral devices.

As just referenced, FIG. 3 illustrates an example of a cross-section of a CMOS device that may be formed using the techniques of FIGS. 1 and 2. In the example of FIG. 3, a PMOS device is illustrated as being formed using a p-doped substrate 302, e.g., a p-type epitaxial layer, which may correspond to the substrate 102 of FIG. 1. A

An n-type deep well NWdeep 304 is illustrated as being formed within the substrate 302, and an n-type shallow well NWshallow 306 is formed between the well NWdeep 304 and a surface of the illustrated PMOS device.

As may be understood from the descriptions of FIGS. 1 and 2, the deep well NWdeep 304 may represent a first well formed using a first mask, such as the mask 106 of FIG. 1. For example, the deep well NWDeep 304 may be formed similarly to the deep well 116, or the deep well 120, of FIG. 1.

Further, the shallow well NWshallow 306 may be formed using a second mask, such as the mask 108 of FIG. 1. For example, the shallow well NWshallow 306 may be formed similarly to the shallow well 140, or the shallow well 144, of FIG. 1.

Although not illustrated in the example of FIG. 3, it will be understood from the above description of FIGS. 1 and 2 that at least one peripheral device may be formed in the substrate 302, as well. For example, another deep well formed using the first mask and another shallow well formed using the second mask may be used to form one or more of the peripheral devices referenced above, and described and illustrated below with respect to FIGS. 5-55, or other peripheral devices.

The PMOS device of FIG. 3 may be isolated from such peripheral devices, and other CMOS devices, using shallow trench isolation (STI) structure(s) 308, 310. A remainder of FIG. 3 illustrates an example PMOS structure, the functionality of which is not described herein, including a source contact 312, an n-type source/drain (SD) region 314, a pSD region 316, and a p-type lightly-doped drain (pLDD) region 318. A drain contact 320 is illustrated as being connected to a pSD region 322 and a pLDD region 324. A p-type polysilicon gate layer 324 is illustrated as being connected to a gate contact 326.

Further, as may be understood from the above descriptions of FIGS. 1 and 2, many of the processing steps used to construct the PMOS device of FIG. 3 may be leveraged or shared in the construction of peripheral devices. For example, the STI structure(s) 308, 310 may isolate the PMOS device of FIG. 3 from the peripheral device(s). Further, layers of the PMOS device of FIG. 3, such as the polysilicon gate layer 324, may be formed at a same time as a polysilicon gate of one or more peripheral devices. Implantations of the various doped regions, such as the nSD region 314, or the pSD region 316, may occur in tandem with corresponding n-type or p-type implantations in a peripheral device(s). Similar comments apply to formation of the various contacts (source contact 312, drain contact 320, and gate contact 326).

FIG. 4 illustrates a cross-section of an example isolation scheme for CMOS devices that may be implemented using the techniques of FIGS. 1 and 2. Specifically, rather than the STI structures 308, 310 of FIG. 3, an isolation scheme is illustrated in which a substrate 402 has deep wells NWdeep 404 and NWdeep 406 formed therein, as well as shallow wells NWshallow 408 and NWshallow 410, and in which isolation is provided by a p-well 412 formed in the substrate 402. That is, FIG. 4 provides a more detailed example of the isolation scheme referenced above with respect to FIG. 1, with respect to the isolation region 156 formed between the shallow well 140 and the shallow well 144.

As referenced above, the techniques of FIGS. 1 and 2 enable a reduction in size of the p-well 412, while still retaining a desired and necessary level of isolation between the shallow wells 408 and 410 (in which, e.g., CMOS devices such as the PMOS device of FIG. 3 may be formed). In particular, the use of multiple masks 106, 108 of FIG. 1 enables the split-well configuration described herein, in which a width(s) of deep wells may be different than a width(s) of narrow wells. Moreover, the finer degree of control afforded by the second, shallow mask 108 of FIG. 1 (as compared to the first, deep mask 106), enables close placement of the shallow wells 408, 410 to one another.

Thus, for example, for CMOS devices for which operational electric fields have a depth dependency, different levels of isolation may be implemented at different depths to avoid undesired effects of such electric fields. In conventional approaches, it may be necessary to maintain a minimum isolation distance determined by a maximum value of an electric field, even when the electric field is weaker at a given depth. In FIG. 4, however, the isolation distances may be customized at different depths to corresponding values of electric fields at those depths.

FIG. 5 illustrates a first example of a peripheral device formed using the techniques of FIGS. 1 and 2, a vertical DMOS. FIG. 6 illustrates an example top view of the vertical DMOS of FIG. 5.

In the example of FIG. 5, a p-type substrate 502 (e.g., an epitaxial layer) has a deep N well (NWdeep) 504 formed therein, analogous to the deep well 112 of FIG. 1. Cross-sectional areas 506, 510 of a diffusion ring formed using a shallow N well are illustrated, along with a central shallow Nwell 508, so that areas 506, 508, 510 are formed between the deep N well 504 and a surface of the substrate 502, and corresponding to an example implementation of the shallow wells 128, 132, 136 of FIG. 1. Thus, the NWdeep 504 may provide, and may be referred to as, a drive region or nDrive 504 of a drain of the vertical CMOS, while the central shallow Nwell 508 provides a drift region, and may be referred to as nDrift. Meanwhile, the outer shallow N well 506, 510 provides a plug or sinker connection between a drain contact 528 and the nDrive region 504, as described in more detail, below, and may be referred to as nPlug or nSinker well(s) 506, 510.

A remainder of FIG. 5 illustrates further elements and aspects of a vertical DMOS. For example, a p-well 512 is illustrated, with p-type region 514 formed adjacent to (encircling) the shallow N well 508. STI 516 provides isolation between the p-well 512 and the shallow Nwell 506, 510.

A source contact 520 is connected by silicide 525 to a p source/drain (pSD) region 522, which is adjacent to an nSD region 524. A nLDD region 526 is formed adjacent to the nSD region 524. An nSD region 530 is formed in the NWshallow/nPlug well 506, and provides a nPlug tap connection via silicide 531 to drain contact 528.

A gate contact 532 is connected to a polysilicon gate 534 by silicide 540, with a gate oxide 536 formed between the polysilicon gate 534 and a surface of the substrate 502. Sidewall spacer 538 is formed around the polysilicon gat 534 and over the nLDD region 526.

Each of the source contact 520, gate contact 532, and drain contact 528 are further illustrated in the top view of FIG. 6. FIG. 6 illustrates a ring nature of the diffusion ring 506/510, as well as the active area of the source contact 520 that is enclosed by the diffusion ring 506/510.

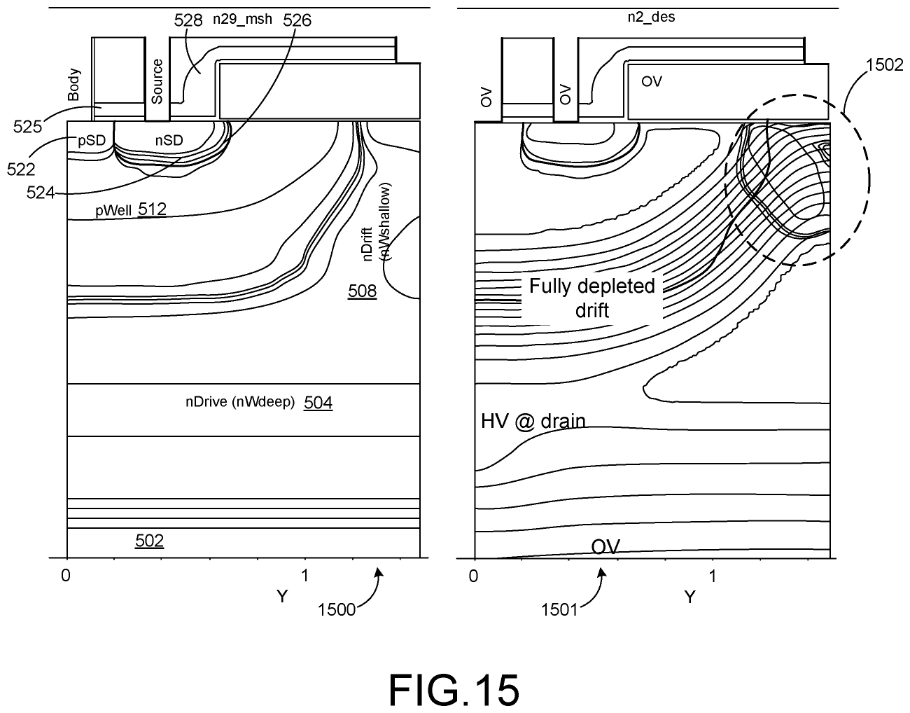

As may be observed, the vertical DMOS of FIGS. 5 and 6 may be implemented with all terminals 520, 528, 532 on a top side surface of the silicon substrate 502. The device is a DMOS device due to the nature of the high voltage, double-diffused drain 504/506/508/510/530, and is referred to as vertical because of the vertical drift present in the double-diffused drain. In various implementations, the device of FIGS. 5 and 6 may have three or four terminals, e.g., Drain, Gate, Source, and Body, where the Source and Body may be electrically tied to make a single terminal, which may be referred to singularly as the source. The body terminal is not illustrated in the example of FIGS. 5, 6, but is illustrated in the example of FIG. 15. The device may be n-type (nVDMOS) or p-type (pVDMOS).

In example implementations, the device of FIGS. 5 and 6 may be implemented to provide a medium or high voltage vertical DMOS that is integrated into a CMOS platform, without requiring any additional process modules beyond those required by the CMOS platform. For example, the described vertical DMOS may be used to provide embedded nonvolatile memory devices using 15V-20V operating voltages. Using the techniques described herein, such memory modules may be included without adding to the manufacturing complexity and cost of associated products. The vertical DMOS of FIGS. 5 and 6 may be used for various other applications requiring a medium or high voltage operating range, as well.

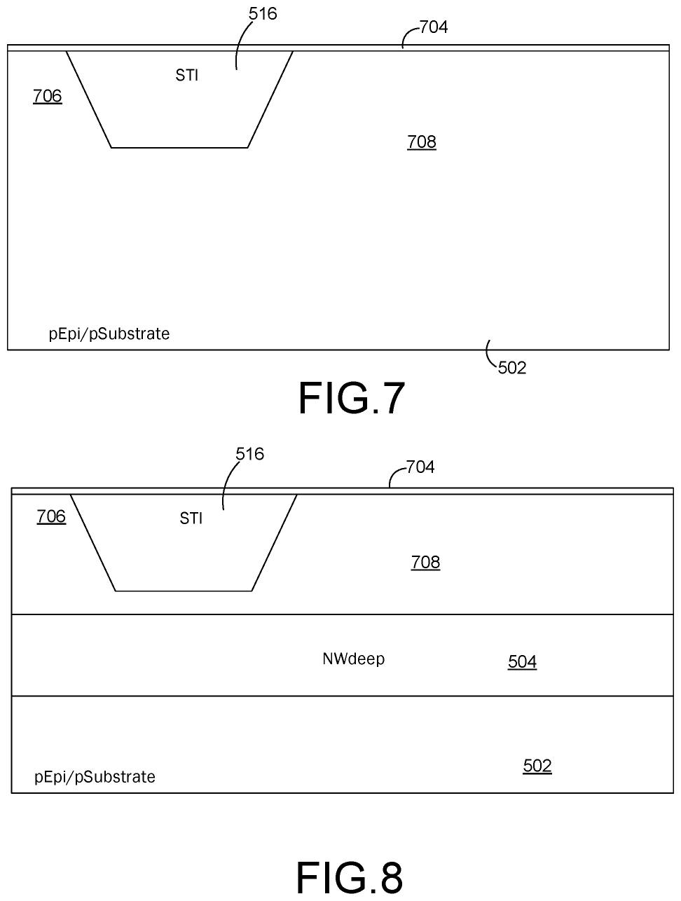

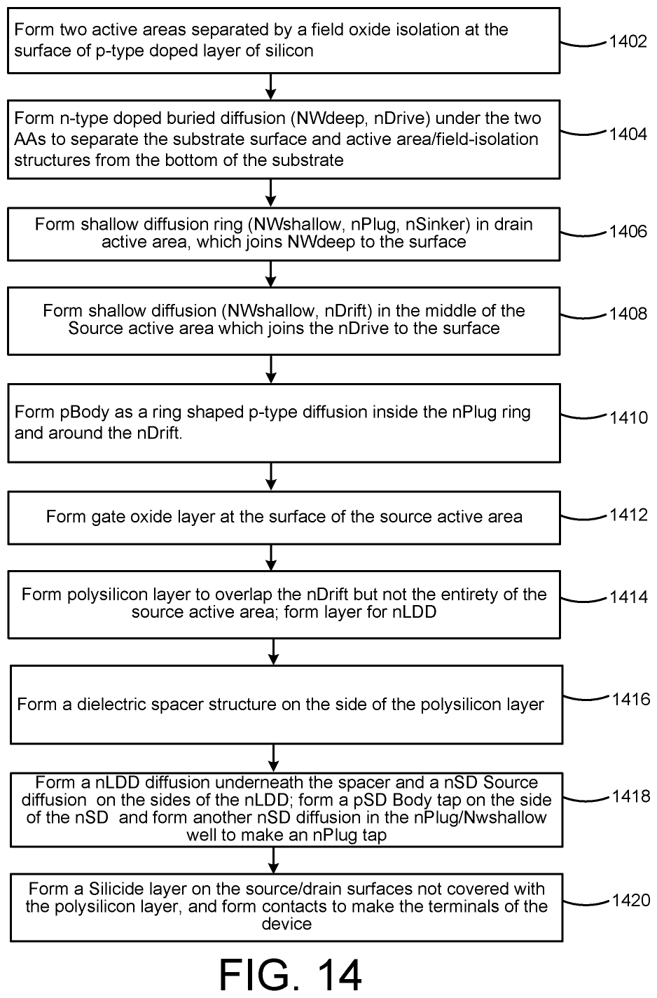

FIGS. 7-13 illustrate an example process flow for forming the vertical DMOS of FIGS. 5 and 6, corresponding to the flowchart of FIG. 14. Specifically, FIGS. 7-13 illustrate a half-pitch cross section corresponding to the cross section of FIG. 6. In the following, the descriptions of FIGS. 7-13 are provided with reference to corresponding steps of the flowchart of FIG. 14.

In FIG. 7, two active areas 706, 708 are formed in the substrate 502, separated by a field oxide isolation 516, and using a sacrificial oxide growth 704 as described in more detail, below (1402). As also described, the active area 706 may be used to form a drain of the vertical DMOS, while the active area 708 may be used to form a source of the vertical DMOS.

In FIG. 8, an n-type doped buried diffusion layer 504, referred to herein as NWdeep, may be formed under the two active areas 706, 708, in order to separate the substrate surface (including the active areas 706, 708 and the isolation structure 516) from a bottom of the substrate 502 (1404). For example, the NWdeep layer 504 may be formed using the deep mask 106 of FIG. 1. As also understood from FIGS. 1-4, the NWdeep well 504 may be formed during a same, dedicated masking step as one or more deep n-wells of CMOS structures formed in the substrate 502 (e.g., using a deepest implant(s) of the CMOS nWell implant chain), such as the well NWdeep 304 of FIG. 3. As referenced above, the NWdeep well 504 may be used as, and referred to as, the nDrive well of the vertical DMOS being formed.

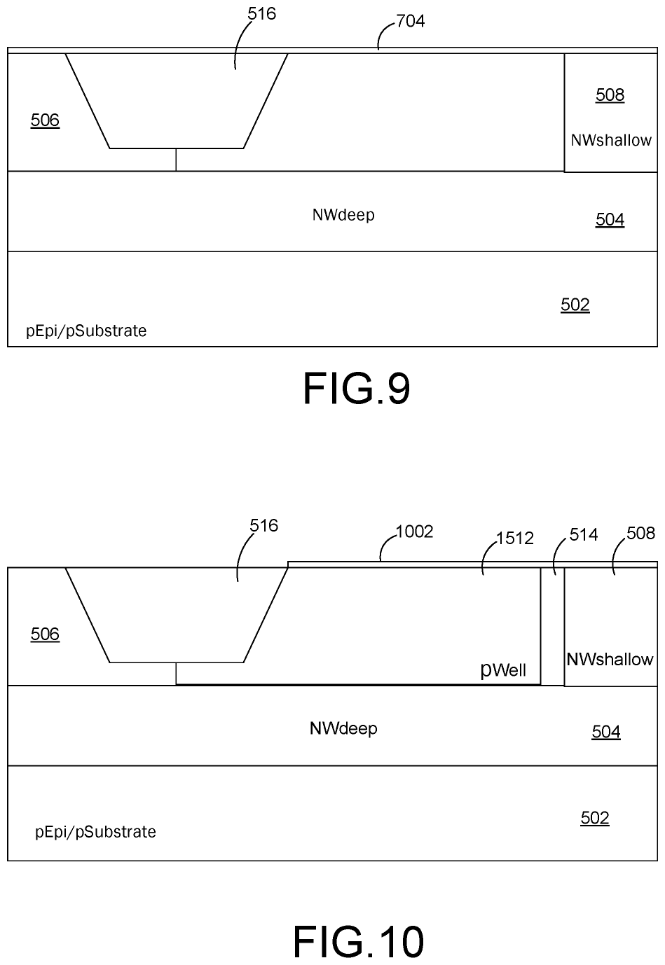

In FIG. 9, a shallow diffusion ring (NWshallow) 506, 510 may be formed in the drain active area 708, which joins the NWdeep 504 to the surface of the substrate 502 (1406). As referenced, the NWshallow ring 508 may be referred to as nPlug, or nSinker. Also in FIG. 9, the NWshallow well 508 is formed in the source active area 706 and joins NWdeep, nDrive 504 to the surface of the substrate 502 (1408), where, as referenced above, the NWshallow well 508 may be referred to as nDrift.

The wells 506, 508 may be formed through one dedicated masking step, e.g., using the shallow mask 108 of FIG. 1, out of the shallowest implants of the CMOS nWell implants chain. As described, using the shallow mask 108 of FIG. 1 enables separation of shallow implants from the standard CMOS flow, and enables use of a thinner photoresist mask and associated smaller critical dimensions. Thus, although shown in separate steps in FIG. 14, it will be appreciated that steps 1408, 1410 may be executed in parallel, as part of the same dedicated masking step.

In FIG. 10, the Pwell 512 is formed, leaving the p-region 514 surrounding the NWshallow (nDrift) well 508 (1410). More specifically, the Pwell (also referred to as pBody) may be formed as a ring shaped p-type diffusion inside the nPlug ring 506 and around the nDrift well 508. The Pwell 512 (pBody) may be formed out of all or the shallowest implants of the CMOS pWell implants chain. For example, if formed out of part of the pWell implant chain, then the Pwell 512 may be implanted out of a dedicated mask, similar to the dedicated masks 106, 108 of FIG. 1, and providing an example of the intra-module processing 160 of FIG. 1. In example implementations, the pBody diffusion 512 reaches the substrate 502 surface and does not completely counter-dope the buried nDrive 504.

A gate oxide layer 1002 may be formed at the surface of the source active area 708 (1412). For example, the oxide layer 1002 may be formed separately following removal of oxide 704.

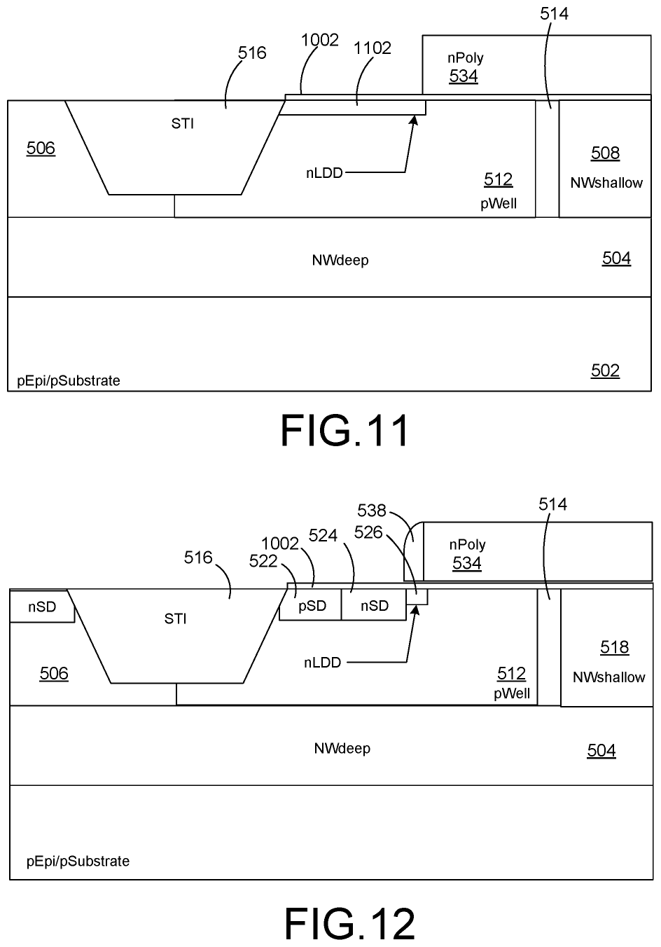

In FIG. 11, a polysilicon layer 534 is formed to overlap the NWshallow/nDrift 508 and a portion of the pWell 512, and a layer 1102 is formed (1414). As shown in FIG. 12, the layer 1102 may be a lightly-doped n-type layer, a portion of which is used to form nLDD 526.

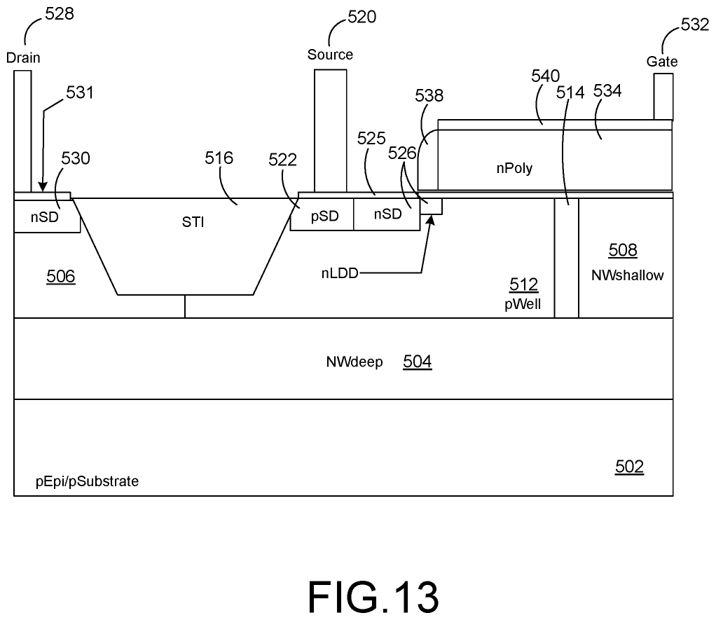

Specifically, in FIG. 12, a dielectric spacer structure 538 is formed on the side of the polysilicon layer 534 (1416). Then, the body tap pSD 522 and nSD 524 are formed, to also define the nLDD 526, as referenced above, along with forming the drain region nSD 530 that defines an nPlug tap (1418). As shown in FIG. 13, a silicide layer 525, 531 may be formed on the surface of drain/source regions not covered with the polysilicon layer 534, and contacts 520, 528, 532 may be formed to make the terminals of the device (1420).

In example implementations, all of the processing steps of FIGS. 10-13, e.g., steps 1410-1420, may be formed using leveraged, shared processing steps of a standard CMOS flow. In particular, the vertical DMOS of FIGS. 5-14 may be formed with a HV drain using a CMOS drain contact 528, CMOS silicide 531, and CMOS nSD diffusion 530. Meanwhile, the NWshallow well 506, 510 provides the nPlug region separately from the NWdeep well 504 used to provide the nDrive region, and the NWshallow well 508 provides nDrift depleted by the n-type polysilicon layer 534 and the pWell 512.

In FIG. 15, a cross section simulation 1500 provides an example of the vertical DMOS of FIGS. 5 and 6, with corresponding labels. Simulation view 1501 illustrates corresponding electric field distributions, including a region 1502 illustrated full depletion of the drift region 508.

Thus, the CMOS Pwell 512 is illustrated as being vertically enclosed by nDrive/NWdeep 504 and laterally enclosed by nDrift/NWshallow 508, the former of which isolates the source/body from the bulk of the substrate 502, and the latter of which provides the depleted drift region 1502 for the HV device, as just referenced. In other words, HV drain is obtained by full depletion of the vertical drift 1502.

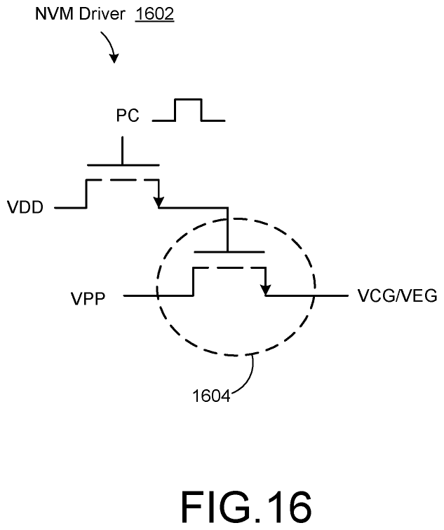

In FIG. 16, an example circuit application is provided using the vertical DMOS of FIGS. 5-15, a HV Driver 1602 for Nonvolatile Memory. In FIG. 16, the transistor 1604 may be implemented using the above techniques to provide a high-side, bootstrapped HV switch. The transistor 1604 may be implemented with a drain at VPP providing a shared drain with shared drain diffusions, and with a HV source relative to a substrate.

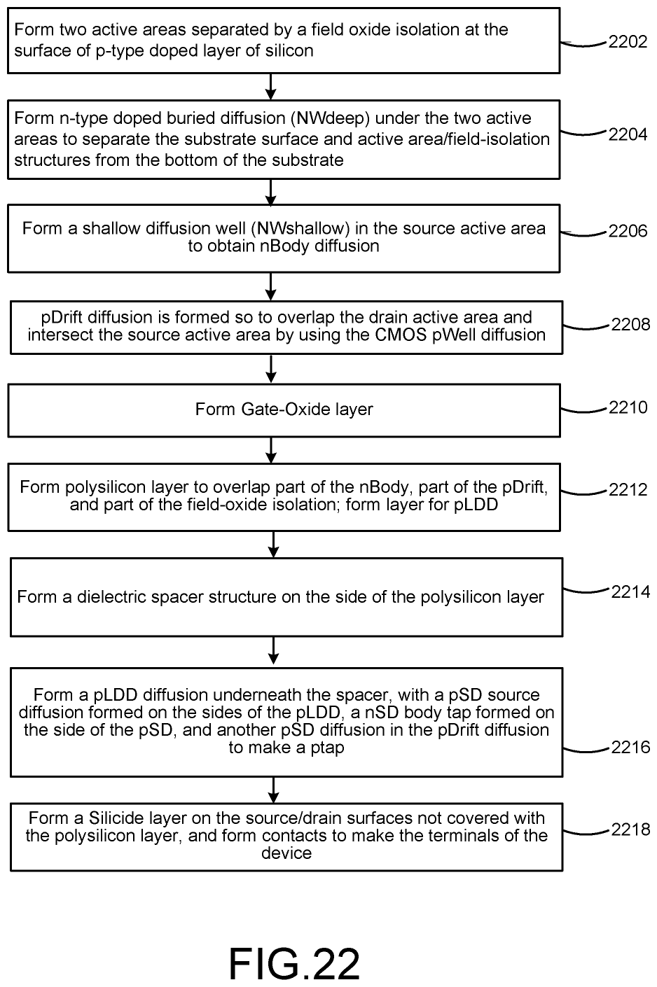

FIGS. 17-23 illustrate example implementations and aspects of a second example peripheral device using the techniques of FIGS. 1 and 2, a lateral DMOS. Specifically, FIGS. 17-23 illustrate and describe formation of a half-pitch cross section of a lateral DMOS. In the following, the descriptions of FIGS. 17-21 are provided with reference to corresponding steps of the flowchart of FIG. 22.

In FIG. 17, two active areas 1700, 1701 are formed in a substrate 1702, separated by field oxide isolation regions 1704, 1706, and using a sacrificial oxide growth 1708 (2202). As described below, the active area 1700 may be used to form a body and source of the lateral DMOS, while the active area 1701 may be used to form a drain of the lateral DMOS.

Also in FIG. 17, an n-type doped buried diffusion layer 1710, referred to herein as NWdeep, may be formed under the two active areas 1700, 1701, in order to separate the substrate surface (including the active areas 1700, 1701 and the isolation structures 1704, 1706) from a bottom of the substrate 1702 (2204). For example, the NWdeep layer 1710 may be formed using the deep mask 106 of FIG. 1. As also understood from FIGS. 1-4, the NWdeep well 1710 may be formed during a same, dedicated masking step as one or more deep n-wells of CMOS structures formed in the substrate 1702 (e.g., using a deepest implant(s) of the CMOS nWell implant chain), such as the well NWdeep 304 of FIG. 3. The NWdeep well 1710 may be used as, and referred to as, the Reduced Surface Field (RESURF) diffusion well of the lateral DMOS being formed.

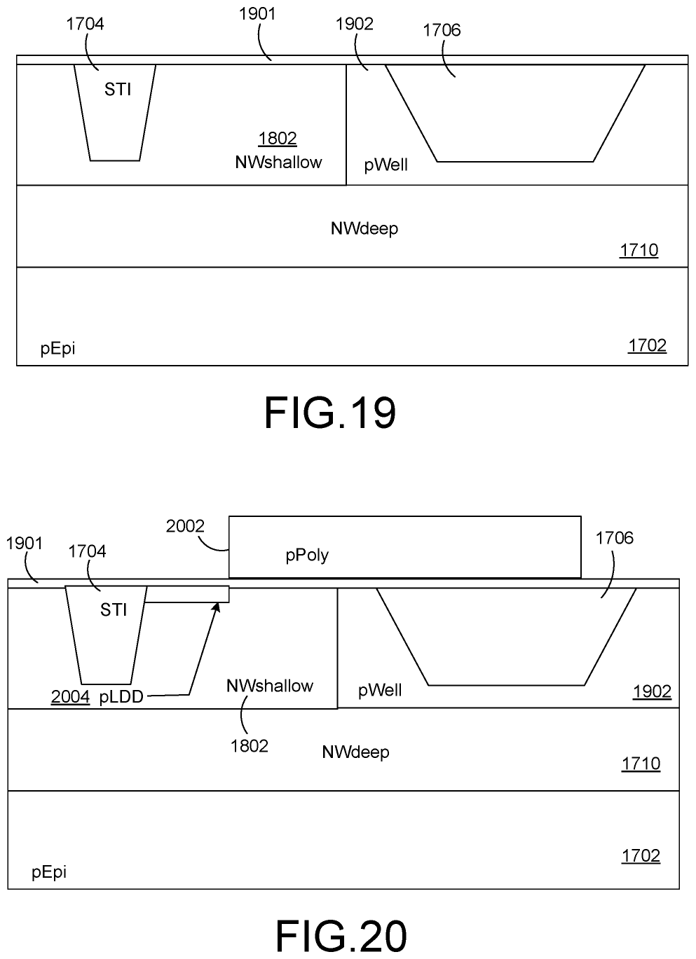

In FIG. 18, a shallow diffusion well (NWshallow) 1802 may be formed in the source active area 1700, which joins the NWdeep 1710 to the surface of the substrate 1702 (2206). In FIG. 19, a pDrift diffusion 1902 may be formed so to overlap the Drain active area 1701 and intersect the source active area 1700 by using a pWell diffusion process of the CMOS platform (2208). For example, if formed out of part of the pWell implant chain of the CMOS platform, then the pDrift diffusion 1902 may be implanted out of a dedicated mask, similar to the dedicated masks 106, 108 of FIG. 1. The nBody diffusion (NWShallow) 1802 may be formed as a doughnut shaped n-type diffusion around the pDrift diffusion 1902.

The well 1802 may be formed through one dedicated masking step, e.g., using the shallow mask 108 of FIG. 1, out of the shallowest implants of the CMOS nWell implants chain. As described, using the shallow mask 108 of FIG. 1 enables separation of shallow implants from the standard CMOS flow, and enables use of a thinner photoresist mask and associated smaller critical dimensions.

A gate oxide layer 1901 may be formed (2210). For example, the oxide layer 1901 may be formed separately following removal of oxide 1708. In FIG. 20, a polysilicon layer 2002 (e.g., p-doped) may be formed to overlap part of the nBody 1802, part of the pDrift 1902, and part of the field-oxide isolation 1706, and a pLDD layer 2004 may be formed (2212).

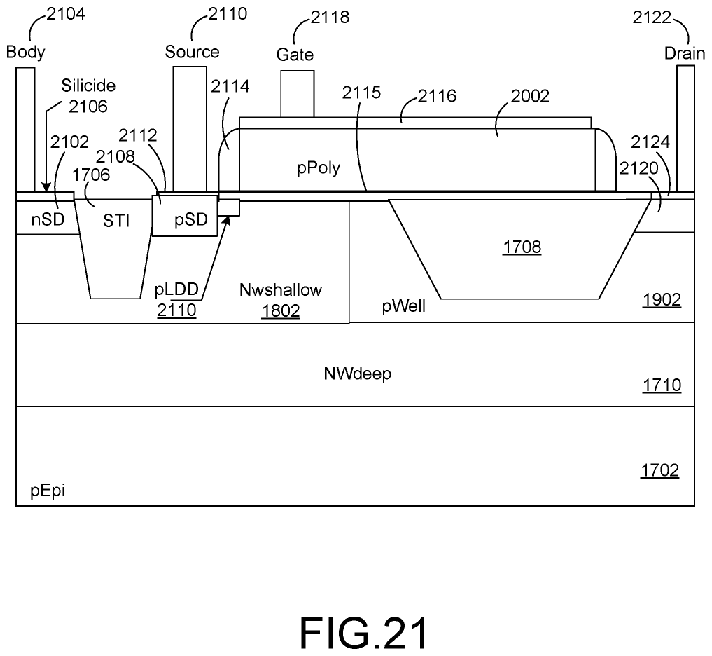

In FIG. 21, a dielectric spacer structure 2114 is formed on the side of the polysilicon layer 2002 (2214), made of a suitable oxide or nitride. Then, a pLDD diffusion 2101 may be defined under the spacer 2114, with a pSD source diffusion 2108 formed on the sides of the pLDD 2101, an nSD body tap 2102 formed on the side of the pSD 2108, and another pSD diffusion 2124 formed in the pDrift diffusion 1902 to make a ptap contact.

As also shown in FIG. 21, silicide 2106, 2112 and 2124 may be formed on the surface of drain/source regions not covered with the polysilicon layer 534, and contacts 2104, 2110, 2118, and 2122 may be formed to make the terminals of the device (2218).

In example implementations, all of the processing steps of FIGS. 19-21, e.g., steps 2208-2218, may be formed using leveraged, shared intra-module processing steps (e.g., masks) 160 of a standard CMOS flow. In particular, the lateral DMOS of FIG. 21 may be formed with a HV drain using a CMOS drain contact 2122, CMOS silicide 2124, and CMOS pSD diffusion 2120. Meanwhile, the NWshallow well 1802 provides the body diffusion, while the NWdeep well 1710 provides resurf diffusion.

The lateral DMOS of FIGS. 17-23 may be used to provide a medium or high voltage, lateral DMOS integrated into a CMOS platform, with no added process modules beyond the conventional CMOS processing. The lateral DMOS of FIGS. 17-23 may be used for embedded nonvolatile memory IPs requiring, e.g., 15v-20v operating voltages. Using the techniques described herein, such memory IP does not add to the manufacturing complexity or cost of the resulting products. The described lateral DMOS may be used for applications other than nonvolatile memory applications, as well.

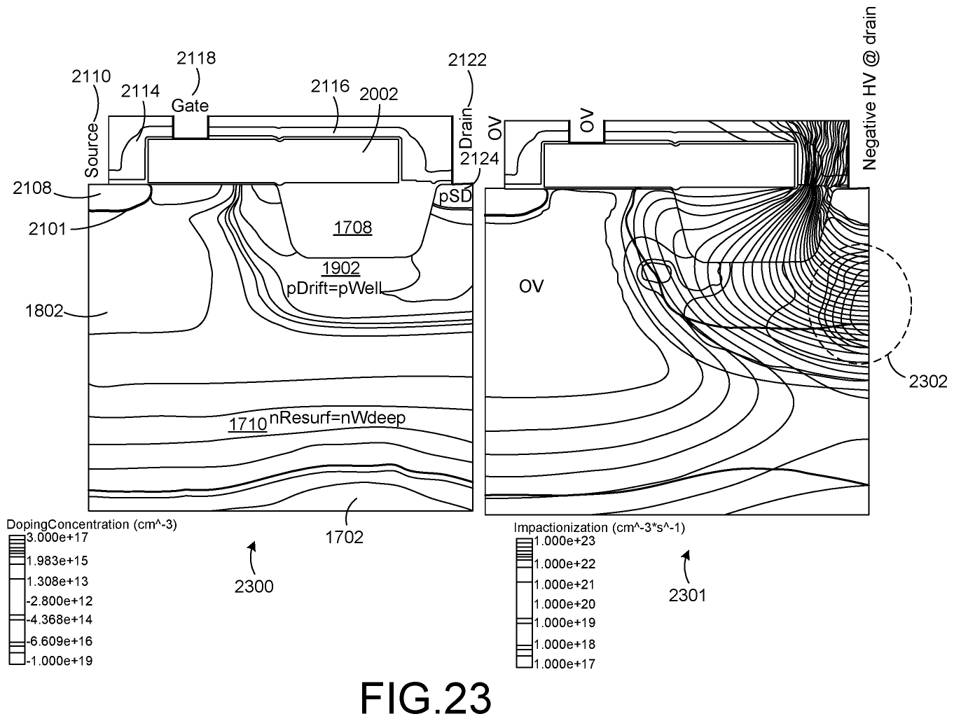

In FIG. 23, a cross section simulation 2300 provides an example of the lateral DMOS of FIG. 21, with corresponding labels. Simulation view 2301 illustrates corresponding electric field distributions, including a region 2302 illustrating full depletion of the drift region 1902.

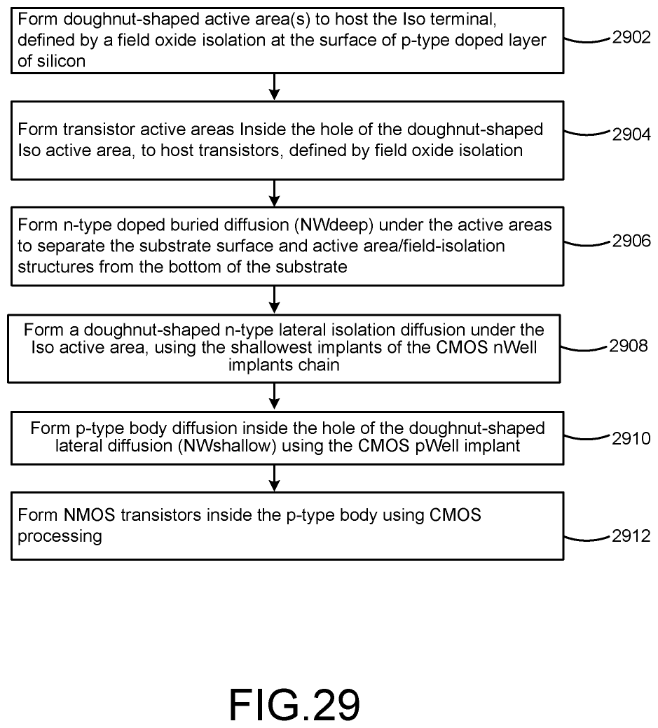

FIGS. 24-32 illustrate example implementations and aspects of a third example peripheral device formed using the techniques of FIGS. 1 and 2, a floating body low-voltage (LV) NMOS. In the following, the descriptions of FIGS. 24-28 are provided with reference to corresponding steps of the flowchart of FIG. 29.

In the following, the described floating body LV NMOS shown in cross-section provides a low-voltage n-type mosfet formed in a pWell isolated from pEpi/pSubstrate, with five terminals: drain, gate, source, body, and isolation (ISO). The body terminal can be biased independently of the pSubstrate/ground, the iso terminal may be biased at a higher voltage than both the pSubstrate and the Body, and the body and iso terminals may be tied together.

In FIG. 24, doughnut-shaped active area(s) 2406 may be formed to host the above-referenced iso terminal of the floating body LV NMOS, defined by a field oxide isolation 2408 at the surface of p-type doped layer of silicon substrate 2402 (2902). Transistor active area(s) 2404 may be formed inside the hole of the doughnut-shaped Iso active area 2406, to host transistors, and defined by field oxide isolation 2410 (2904).

Then, n-type doped buried diffusion (NWdeep) 2412 may be formed under the active areas 2404, 2406 to separate the substrate surface and active area/field-isolation structures from the bottom of the substrate 2402 (2906). For example, the NWdeep layer 2412 may be formed using the deep mask 106 of FIG. 1. As also understood from FIGS. 1-4, the NWdeep well 2412 may be formed during a same, dedicated masking step as one or more deep n-wells of CMOS structures formed in the substrate 2402 (e.g., using a deepest implant(s) of the CMOS nWell implant chain), such as the well NWdeep 304 of FIG. 3.

In FIG. 25, a doughnut-shaped n-type lateral isolation diffusion 2502 may be formed under the Iso active area 2406, using the shallowest implants of the CMOS nWell implants chain (2908). The well 2502 may be formed through one dedicated masking step, e.g., using the shallow mask 108 of FIG. 1, out of the shallowest implants of the CMOS nWell implants chain. As described, using the shallow mask 108 of FIG. 1 enables separation of shallow implants from the standard CMOS flow, and enables use of a thinner photoresist mask and associated smaller critical dimensions.

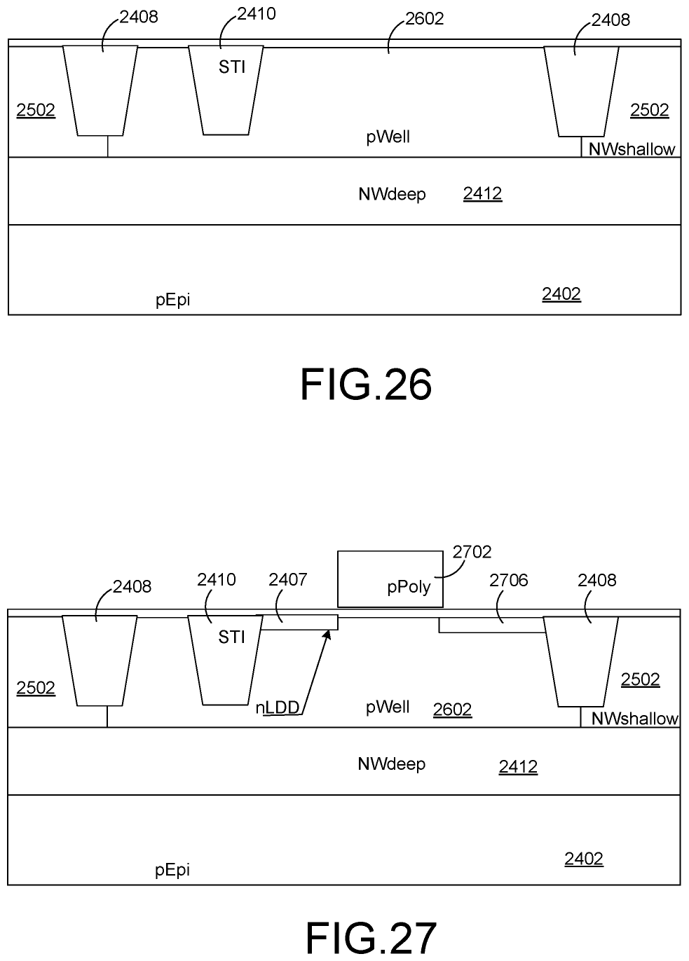

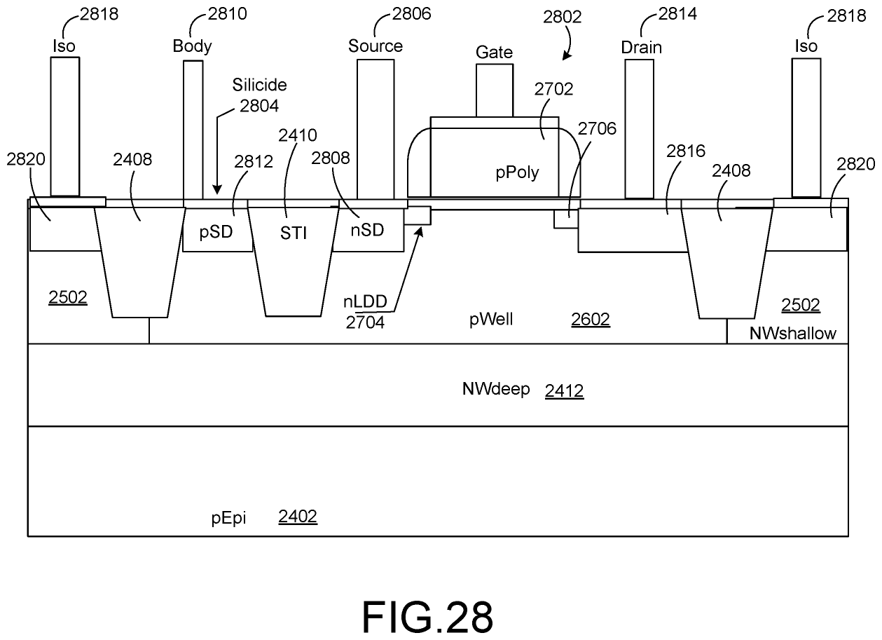

In FIG. 26, a p-type body diffusion 2602 may be formed inside the hole of the doughnut-shaped lateral diffusion (NWshallow) 2502, using the CMOS pWell implant (2910). Then, as demonstrated in FIGS. 27 and 28, NMOS transistors may be formed inside the p-type body 2602, using CMOS processing (2912).

In particular, in FIG. 27, and analogous to the descriptions of transistor formation provided above with respect to FIGS. 3, 10-13, and 19-21, a gate polysilicon layer 2702 may be formed, along with source nLDD layer 2704 and drain nLDD layer 2706.

In FIG. 28, a gate structure 2802 is completed using the gate polysilicon layer 2702, and a layer of silicide 2804 is provided at the surface of the substrate 2402 not covered by, or including, the gate structure 2802 or the oxide isolations 2408, 2410. A source terminal 2806 is thereby connected to a nSD region 2708, while similarly, a body terminal 2810 is connected to a pSD region 2812. A drain terminal 2814 is connected to a nSD region 2816. Finally, the Iso terminal 2818 is connected to an Iso nDS region 2820.

In example implementations, all of the processing steps of FIGS. 24-28, e.g., steps 2908-2912, may be formed using leveraged, shared intra-module processing steps (e.g., masks) 160 of a standard CMOS flow.

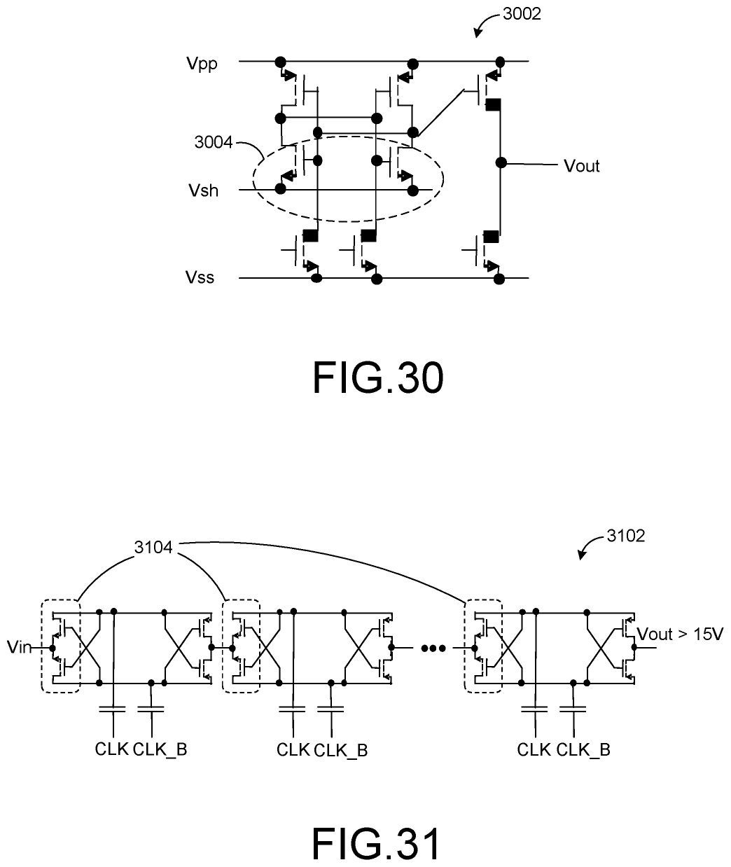

FIG. 30 is a first example circuit built using the LV floating body NMOS of FIGS. 24-29. FIG. 30 illustrates a HV Driver 3002 for Nonvolatile Memory, including an example implementation 3004 of the described LV floating body NMOS.

FIG. 31 is a second example circuit built using the LV floating body NMOS of FIGS. 24-29. FIG. 31 illustrates a charge pump 3102, including an example implementation 3104 of the described LV floating body NMOS.

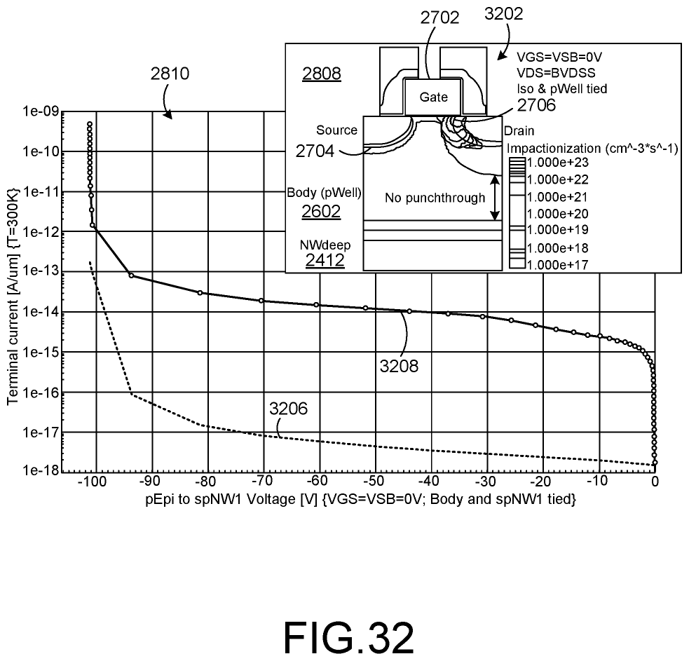

FIG. 32 is a cross section of a simulation 3202 of the LV floating body NMOS of FIGS. 24-29, and an associated current-voltage graph 3204. Simulation view 3202 illustrates corresponding electric field distributions. As shown in FIG. 32, the floating body NMOS device provides vertical isolation, which allows high-voltage p-body bias (shown by curve 3206) relative to p-epi/p-substrate (shown by curve 3208). Low voltage operation is guaranteed when NWdeep 2412 does not interfere with the highest device voltage configuration (e.g., BVdss).

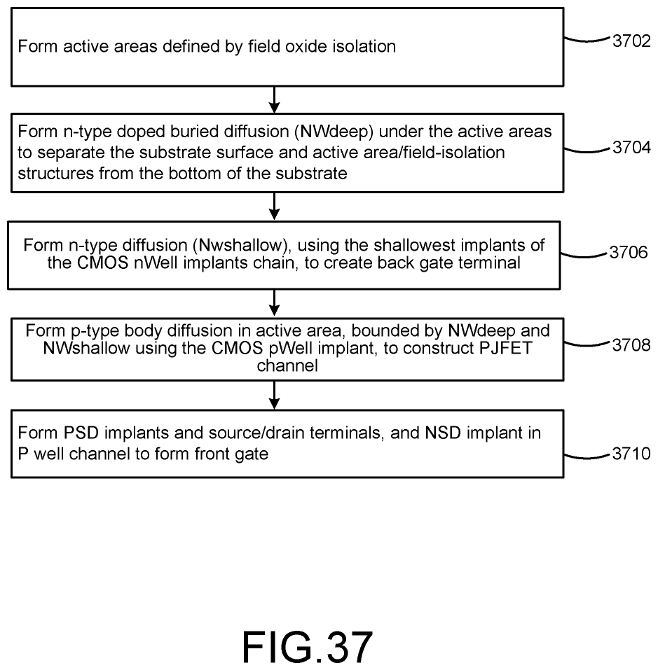

FIGS. 33-43 illustrate example implementations and aspects of a fourth example peripheral device using the techniques of FIGS. 1 and 2, an isolated junction field effect transistor (JFET). In the following, the descriptions of FIGS. 33-36 are provided with reference to corresponding steps of the flowchart of FIG. 37.

In FIG. 33, active area(s) 3304 defined by field oxide isolation 3306 are formed in a p-type substrate 3302 (3702). Then, n-type doped buried diffusion (NWdeep) 3308 is formed under the active area 3304 to separate the substrate surface and active area/field-isolation structures from the bottom of the substrate (3704). For example, the NWdeep layer 3308 may be formed using the deep mask 106 of FIG. 1. As also understood from FIGS. 1-4, the NWdeep well 3308 may be formed during a same, dedicated masking step as one or more deep n-wells of CMOS structures formed in the substrate 3302 (e.g., using a deepest implant(s) of the CMOS nWell implant chain), such as the well NWdeep 304 of FIG. 3.

In FIG. 34, n-type diffusion (Nwshallow) 3402 may be formed, using the shallowest implants of the CMOS nWell implants chain, which may be used to create a back gate terminal of the JFET, as described and illustrated below (3706). The well 3402 may be formed through one dedicated masking step, e.g., using the shallow mask 108 of FIG. 1, out of the shallowest implants of the CMOS nWell implants chain. As described, using the shallow mask 108 of FIG. 1 enables separation of shallow implants from the standard CMOS flow, and enables use of a thinner photoresist mask and associated smaller critical dimensions.

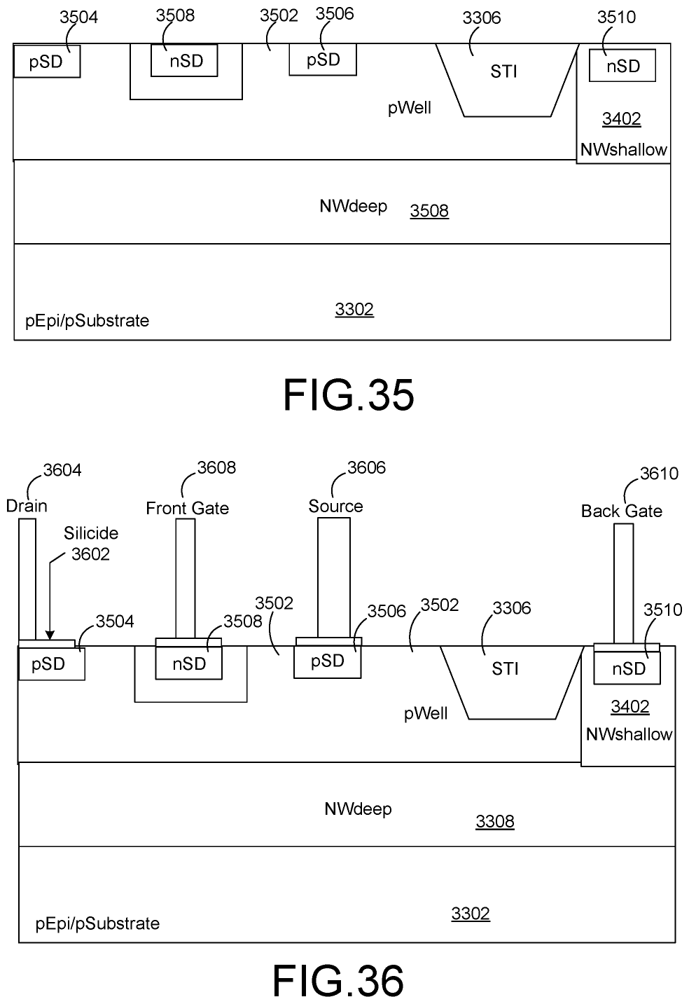

In FIG. 35, a p-type body diffusion 3502 may be formed in the active area 3304, bounded by NWdeep 3308 and NWshallow 3402, and using the CMOS pWell implant, to construct a PJFET channel (3708). Then, with reference to FIGS. 35 and 36, pSD implants 3504, 3506 and source/drain terminals 3604, 3606 may be formed, while an nSD implant 3508 may be formed in the Pwell channel 3502 to form a front gate and front gate terminal 3608, and nSD implant 3510 may be formed in NWshallow 3402 to form the back gate and back gate terminal 3610 (3710).

In example implementations, some of the processing steps of FIGS. 33-36, e.g., steps 3702, 3708, 3710, may be formed using leveraged, shared intra-module processing steps (e.g., masks) 160 of a standard CMOS flow.

Low/medium voltage lateral isolated JFET devices built using the techniques of FIGS. 33-37 may be used, e.g., for low frequency and/or low noise applications, with significant reduction in amplifier noise. In the P-JFET channel 3502 isolated by shallow and deep split Nwell implants 3308, 3402, channel current may be turned off by applying positive voltage to front gate 3608, 3508 and back gate 3610/3510/3402. The illustrated device is thus fully isolated from the P-EPI/psubstrate 3302 by the deep (vertically) N-well NWdeep 3308 and shallow (laterally) split N-well 3402. The device is normally on, operates in negative voltage in conduction mode, and uses positive voltage on the front gate 3608 and back gate 3610 to turn the device off. Further, the device is compatible for use in designs without the split Nwell feature; the Nwell of standard CMOS devices may be constructed from NWdeep and NWshallow to assure industry standard for Pwell isolation and latch-up immunity.

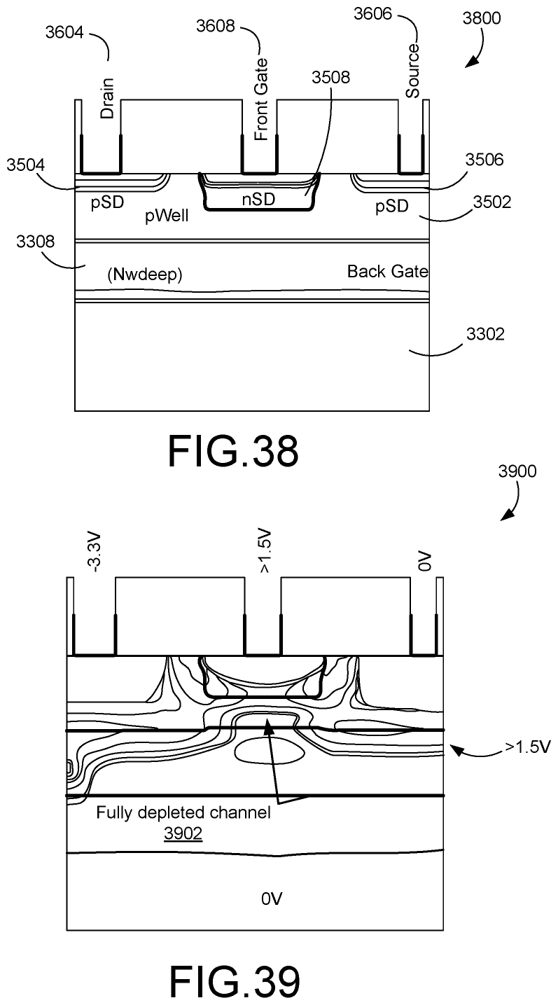

FIG. 38 is a first cross section of a simulation of the JFET of FIGS. 33-37. In FIG. 38, a cross section simulation 3800 provides an example of the JFET of FIG. 36, with corresponding labels. In FIG. 39, simulation view 3900 illustrates corresponding electric field distributions, including a region 3902 illustrating the fully depleted channel of the illustrated JFET. FIGS. 38 and 39 illustrate that NWdeep 3308 isolates the P-JFET from the bulk substrate 3302, and may also be used as the back gate of the device (not shown in FIGS. 38, 39. Further, in some implementations, NWdeep 3308 may be configured to partially counter dope the Pwell 3502 and extend control of the front gate 3608.

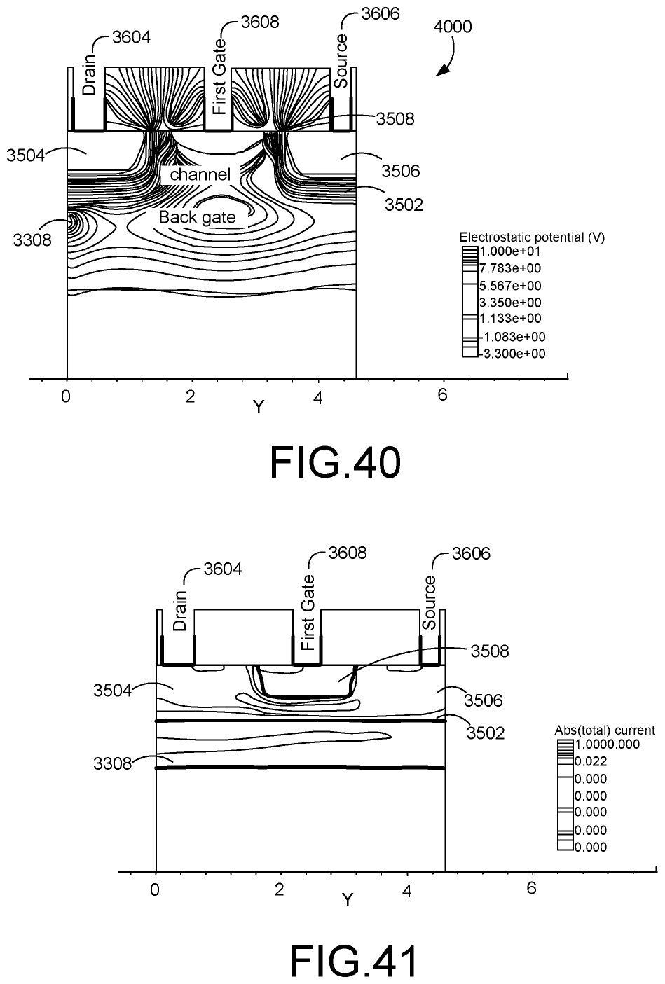

FIG. 40 is a third cross section of an electrical simulation of the JFET of FIGS. 33-37, and FIG. 41 is a fourth cross section of an electrical simulation of the JFET of FIGS. 33-37. FIG. 40 illustrates a simulation 4000 of an off condition of the JFET device, with a fully depleted channel. FIG. 41 illustrates an on condition and associated current densities.

In the examples of FIGS. 38-41, the corresponding JFET device may thus be implemented as an isolated, normally-on JFET that turns off at a specified voltage, e.g., 1.5V. More specifically, FIGS. 38-41 demonstrate how a P-JFET channel may be fully depleted by applying positive voltage on the front and back gates, and how the P-JFET channel may be normally on when negative voltage is applied on the drain, and the gate voltage is below the threshold voltage (e.g., 1.5V). In some embodiments, an operating voltage may be limited by CMOS well junctions at relatively high voltages (e.g., >10V), and may be adjusted by suitable use of implant spacing and STI isolation.

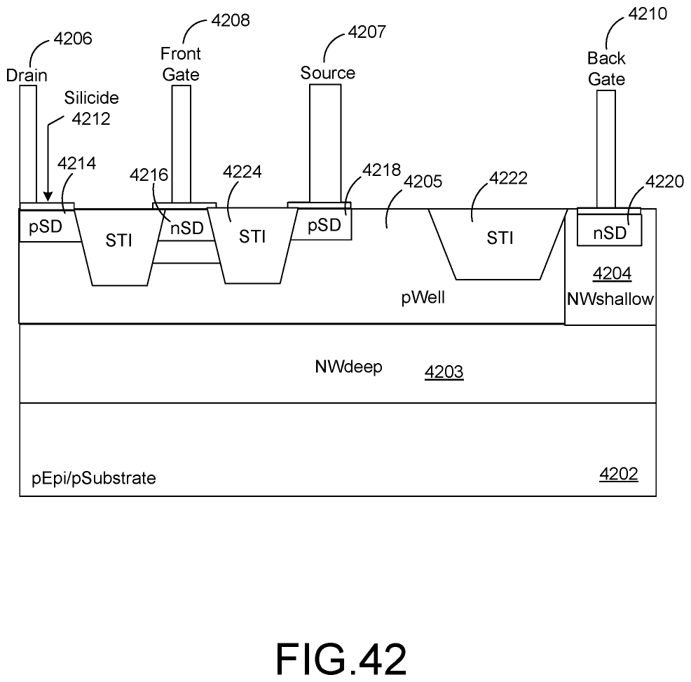

FIG. 42 illustrates a cross section of a second example implementation of a JFET. In FIG. 42, a substrate 4202 has NWdeep well 4203 formed therein, which is connected to NWshallow well 4204. Then, pWell 4205 provides a channel for a JFET device formed with drain 4206, source 4207, front gate 4208, and back gate 4210. A layer of silicide 4212 provides connections between the drain 4206 and pSD region 4214, source 4207 and pSD region 4218, front gate 4208 and nSD region 4216, and between back gate 4210 and nSD region 4220. Isolation is provided by STI 4222, and by STI 4224. In some implementations, a split P-well option may be used to keep only the shallow part of the P-well 4205 in the P-JFET channel.

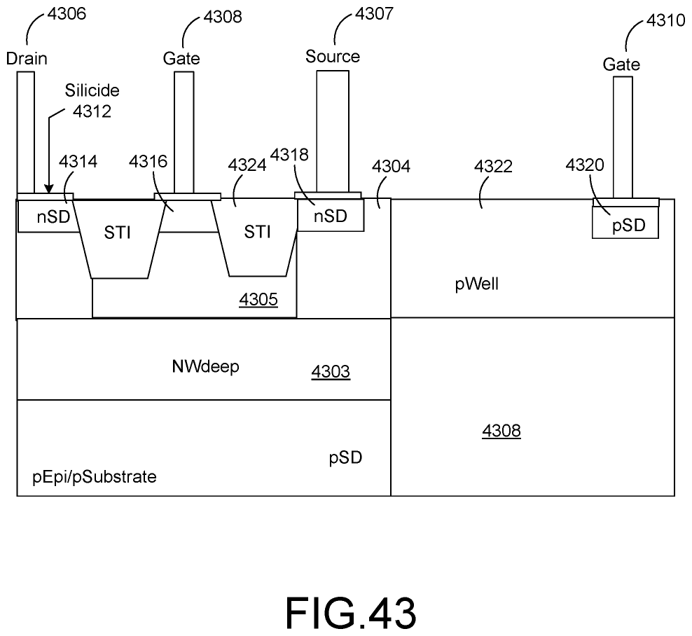

FIG. 43 illustrates a cross section of a third example implementation of a JFET. In FIG. 42, a substrate 4302 has NWdeep well 4303 formed therein, which is connected to NWshallow well 4304 and encapsulates pWell 4305. FIG. 42 provides an embodiment for an N-JFET using the NWdeep Nwell 4303 as a channel for a JFET device formed with drain 4306, source 4307, front gate 4308, and back gate 4310. A layer of silicide 4312 provides connections between the drain 4306 and pSD region 4314, source 4307 and pSD region 4318, front gate 4308 and nSD region 4316, and between back gate 4310 and nSD region 4320. Separate pWell 4322 is provided between the nWshallow well 4304 and the back gate 4310, and isolation is provided by STI 4324. Thus, the p-well 4305 and p-substrate provide front gate 4308 and back gate 4310 terminals, respectively.

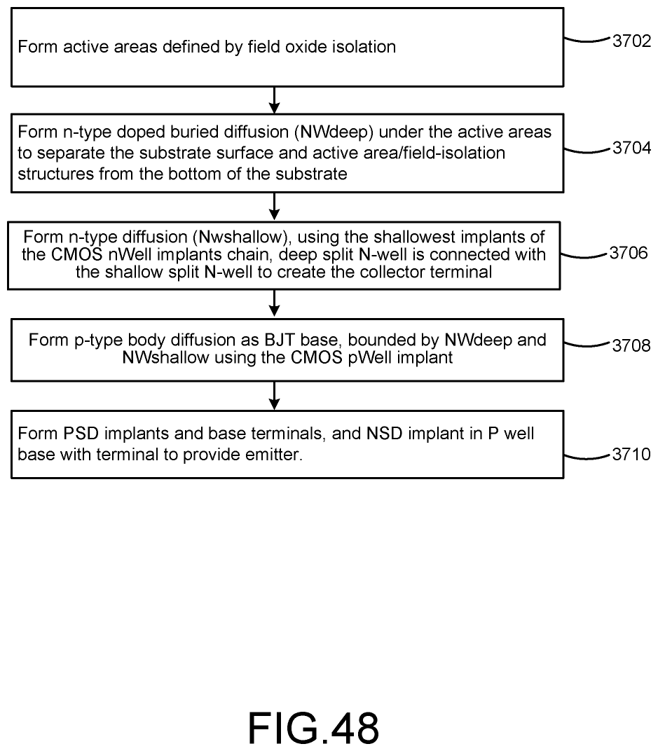

FIGS. 44-55 illustrate example implementations and aspects of a fifth example peripheral device using the techniques of FIGS. 1 and 2, a bipolar junction transistor (BJT). In the following, the descriptions of FIGS. 44-47 are provided with reference to corresponding steps of the flowchart of FIG. 48.

In FIG. 44, active area(s) 4404 defined by field oxide isolation 4406 are formed in a p-type substrate 4402 (4802). Then, n-type doped buried diffusion (NWdeep) 4408 is formed under the active area 4404 to separate the substrate surface and active area/field-isolation structures from the bottom of the substrate 4402 (4804). For example, the NWdeep layer 4408 may be formed using the deep mask 106 of FIG. 1. As also understood from FIGS. 1-4, the NWdeep well 4408 may be formed during a same, dedicated masking step as one or more deep n-wells of CMOS structures formed in the substrate 4402 (e.g., using a deepest implant(s) of the CMOS nWell implant chain), such as the well NWdeep 304 of FIG. 3.

In FIG. 45, n-type diffusion (Nwshallow) 4502 may be formed, using the shallowest implants of the CMOS nWell implants chain, which may be used to create a collector terminal of the BJT, as described and illustrated below (4806). The well 4502 may be formed through one dedicated masking step, e.g., using the shallow mask 108 of FIG. 1, out of the shallowest implants of the CMOS nWell implants chain. As described, using the shallow mask 108 of FIG. 1 enables separation of shallow implants from the standard CMOS flow, and enables use of a thinner photoresist mask and associated smaller critical dimensions.

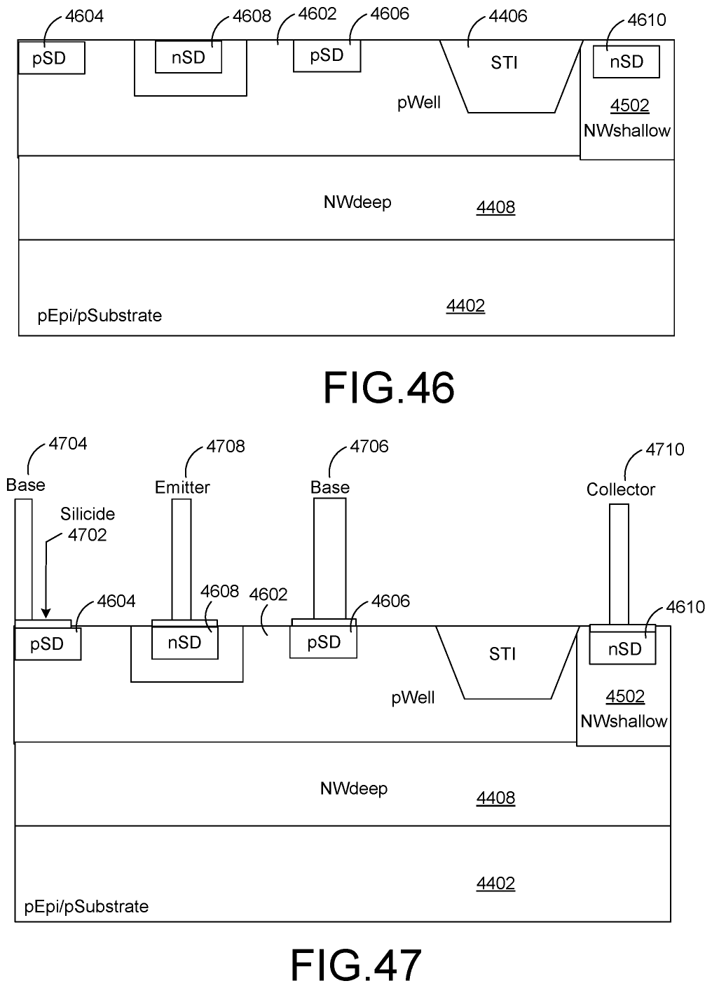

In FIGS. 46 and 47, a p-type body diffusion 4602 may be formed to provide a BJT base, bounded by NWdeep 4408 and Nwshallow 4502 as collector regions, and using the CMOS pWell implant (4808). Then, with reference to FIGS. 46, and 47, pSD implants 4604, 4606 may be formed to enable connection to base terminals 4704, 4706, respectively, using silicide layer 4702, nSD implant 4608 may be formed in the Pwell 4602 providing the BJT base, and may be connected to emitter terminal 4708. Also, nSD implant 4610 may be formed in NWshallow 4502 and connected to collector terminal 4710 (4810).

Thus, FIGS. 44-48 illustrate formation of a vertical BJT with emitter 4708/4608, base 4602/4606, 4706, and collector 4408/4502/4610/4710. Using the techniques described herein, the BJT of FIGS. 44-48 may be constructed with, and provide, a higher gain than a similar BJT formed with conventional methods, due to the lower energy of the split deep Nwell implant. Other implementations are possible, e.g., an nLDD implant may be added to the the nS region 4608 to improve the injection characteristics of the BJT.

In example implementations, some of the processing steps of FIGS. 44-46, e.g., steps 4802, 4808, 4810, may be formed using leveraged, shared intra-module processing steps (e.g., masks) 160 of a standard CMOS flow.

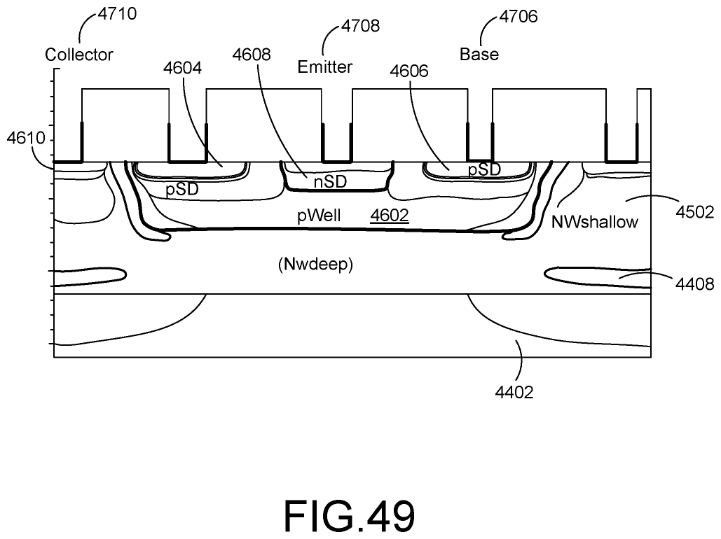

FIG. 49 is a first cross section of a simulation of the BJT of FIGS. 44-48. FIG. 49 illustrates that the Pwell 4602 is vertically enclosed by the NWdeep well 4408 and laterally enclosed by the NWshallow well 4502. Further, the NWdeep well 4408 partially counter dopes the Pwell 4602 and helps to increase the gain of the BJT device.

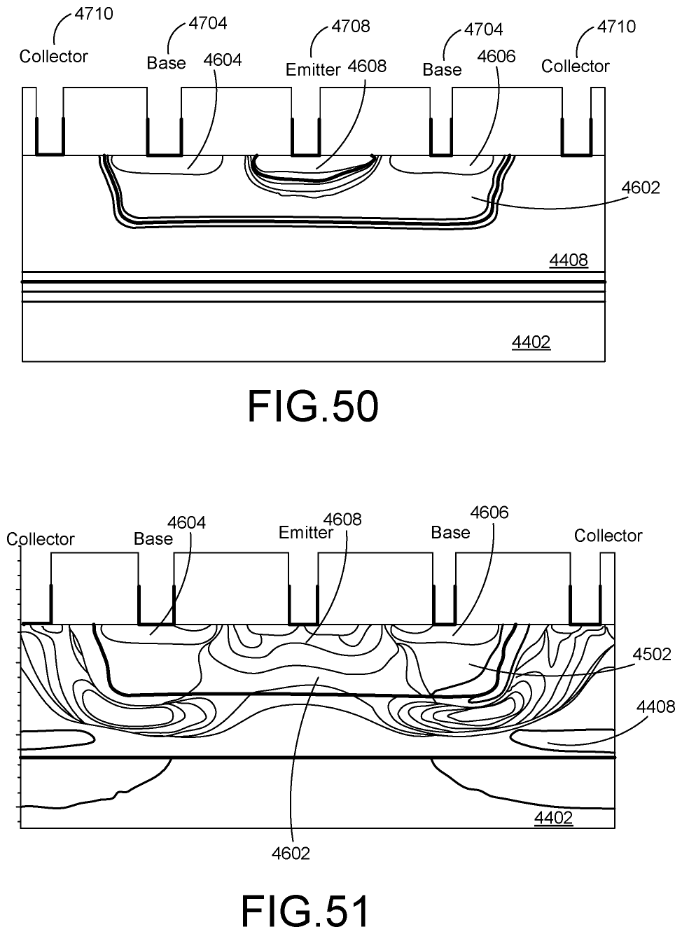

FIG. 50 is a second cross section of a simulation of the BJT of FIGS. 44-48. FIG. 50 illustrates an example electrostatic potential of the BJT device in reverse bias.

FIG. 51 is a third cross section of a simulation of the BJT of FIGS. 44-48. FIG. 51 illustrates an example current flow during a forward operation of the BJT device.

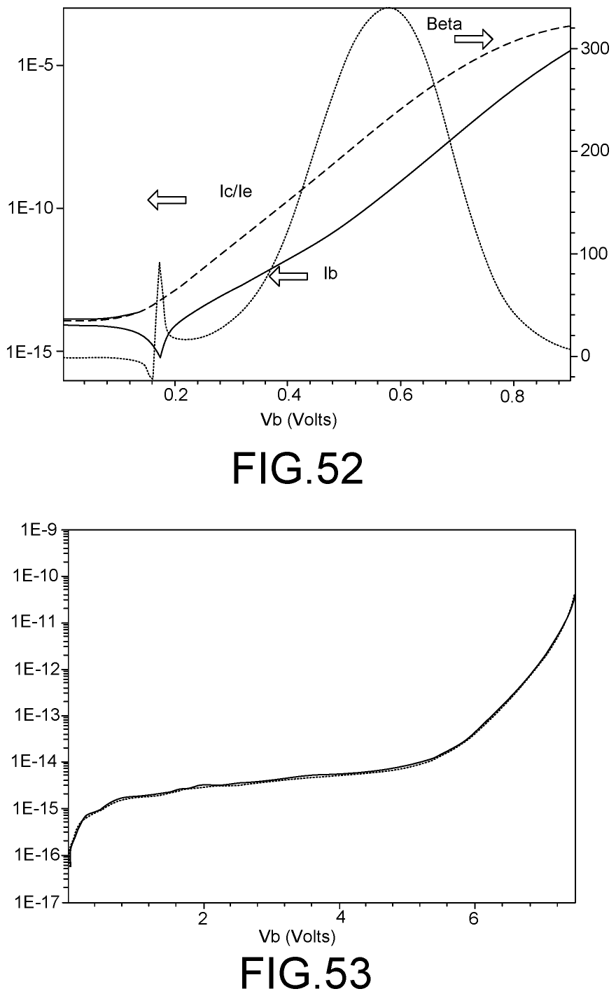

FIG. 52 is a first example current-voltage graph for the BJT of FIGS. 44-48. FIG. 53 is a second example current-voltage graph for the BJT of FIGS. 44-48.

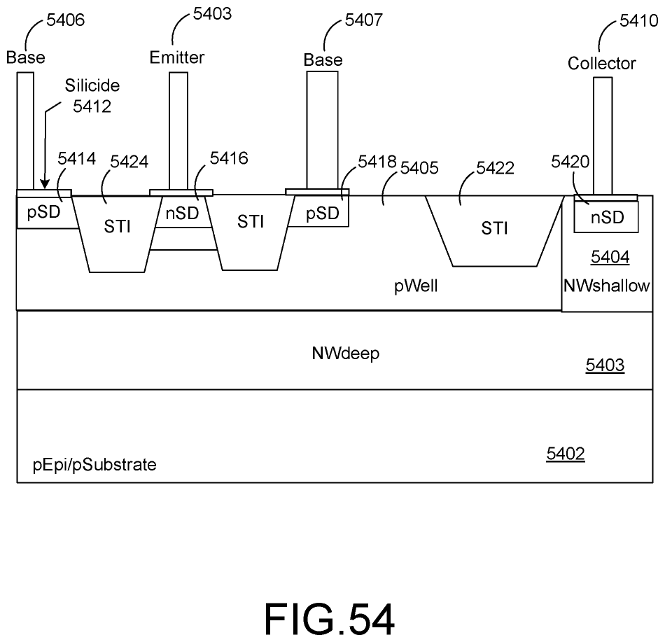

FIG. 54 illustrates a cross section of a second example implementation of a BJT. In FIG. 54, a substrate 5402 has NWdeep well 5403 formed therein, which is connected to NWshallow well 5404. Then, pWell 5405 provides a base for a BJT device formed with base terminals 5406, 5407, emitter 5408 terminal, and collector terminal 5410. A layer of silicide 5412 provides connections between the base terminals 5406, 5407 and pSD regions 5414, 5418, between emitter terminal 5408 and pSD region 5416, and between collector terminal 5410 and nSD region 5420. Isolation is provided by STI 5422, and by STI 5424. In some implementations, a split P-well option may be used to improve control of the BJT base.

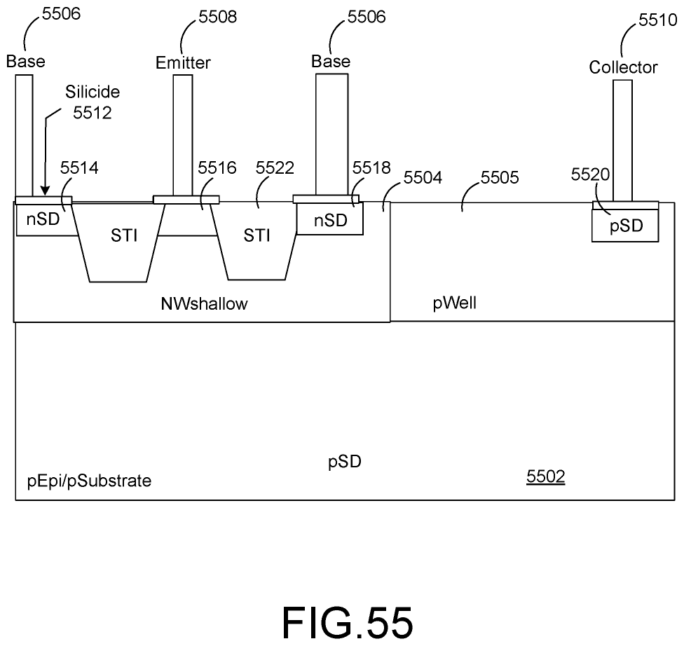

FIG. 55 illustrates a cross section of a third example implementation of a BJT, using a PNP implementation. In FIG. 55, a substrate 5502 has NWshallow well 5404 formed therein as the base. Then, pWell 5505 and the substrate 5502 provide a collector for the BJT device formed with base terminals 5506, 5507, emitter 5508 terminal, and collector terminal 5510. A layer of silicide 5512 provides connections between the base terminals 5506, 5507 and pSD regions 5514, 5518, between emitter terminal 5508 and pSD region 5516, and between collector terminal 5510 and nSD region 5520. Isolation is provided by STI 5522.

In some implementations, a first implantation into a substrate may be performed at a first depth, and defining a first well and a second well laterally spaced from one another within the substrate. A second implantation into the substrate at a second depth may be performed, defining a third well and a fourth well laterally spaced from one another within the substrate, with the second depth being closer to an implant surface of the substrate than the first depth. A CMOS device may be formed using at least the first well and the third well, and a peripheral device may be formed using at least the second well and the fourth well. For example, the first and third well may be used to reconstruct a CMOS well. The various wells may be doped n-type, p-type, or combinations thereof.

The peripheral device may includes a single transistor or field effect device not electrically connected with another transistor or field effect device in a complementary configuration. The peripheral device may be electrically connected to one or more CMOS transistor(s).

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method of making semiconductor devices, comprising:
performing a first implantation into a substrate at a first depth using a first mask, the first mask having at least a first opening defining a first well and a second opening defining a second well;
performing a second implantation into the substrate at a second depth using a second mask, the second mask having at least a third opening defining a third well and a fourth opening defining a fourth well, and the second depth being closer to an implant surface of the substrate than the first depth;
forming a CMOS device using at least the first well and the third well; and
forming a peripheral device using at least the second well and the fourth well.

2. The method of claim 1, further comprising:
forming a device element of the CMOS device and a device element of the peripheral device during a single, shared process.

3. The method of claim 1, wherein the first implantation and the second implantation occur within a single process module.

4. The method of claim 1, further comprising:
performing a fifth implantation into the substrate to form a fifth well, using the first mask and at the first depth;
performing a sixth implantation into the substrate to form a sixth well, using the second mask and at the second depth;
forming a second CMOS device using at least the fifth well and the sixth well, wherein isolation is provided between the CMOS device and the second CMOS device by a portion of the substrate between the third well and the sixth well.

5. The method of claim 4, wherein a distance between the third well and the sixth well is smaller than a distance between first well and the fifth well.

6. The method of claim 1, wherein an active area of the peripheral device is enclosed by the second well and the fourth well.

7. The method of claim 1, wherein the second well and the fourth well are at least partially adjacent to one another in a direction perpendicular to the implant surface, and have different lengths in a direction parallel to the implant surface.

8. The method of claim 1, wherein the peripheral device includes a vertical double-diffused metal oxide semiconductor (DMOS) transistor.

9. The method of claim 1, wherein the peripheral device includes a lateral double-diffused metal oxide semiconductor (DMOS) transistor.

10. The method of claim 1, wherein the peripheral device includes a floating-body MOS transistor.

11. The method of claim 1, wherein the peripheral device includes a junction field effect transistor (JFET).

12. The method of claim 1, wherein the peripheral device includes a bipolar junction transistor (BJT).

13. A method of making semiconductor devices, comprising:
forming CMOS devices of a CMOS platform on a substrate, the CMOS devices being formed using at least a first deep well implanted using a first mask and at least a first shallow well implanted using a second mask; and
forming at least one peripheral device on the substrate, using at least a second deep well implanted using the first mask, and at least a second shallow well implanted using the second mask.

14. The method of claim 13, further comprising:
forming a first device element of the CMOS devices and a second device element of the at least one peripheral device during a single, shared process.

15. The method of claim 14, wherein the substrate is doped a first conductivity type, and the first device element and the second device element include a first well of opposite conductivity type and a second well of opposite conductivity type, respectively.

16. The method of claim 13, wherein the at least one peripheral device includes a vertical double-diffused metal oxide semiconductor (DMOS) transistor.

17. The method of claim 13, wherein the at least one peripheral device includes a lateral double-diffused metal oxide semiconductor (DMOS) transistor.

18. A method of making semiconductor devices, comprising:
forming CMOS devices of a CMOS platform on a substrate, the CMOS devices being formed using at least a first deep well implanted using a first mask and at least a first shallow well implanted using a second mask; and
forming at least one double-diffused metal oxide transistor (DMOS) in the substrate, the DMOS transistor being formed using at least a second deep well implanted using the first mask, and at least a second shallow well implanted using the second mask.

19. The method of claim 18, wherein the at least one DMOS includes a vertical DMOS.

20. The method of claim 18, wherein the at least one DMOS includes a lateral DMOS.
